(19) United States
(12) Patent Application Publication
(10) Pub. No.: US 2024/0431148 A1
(43) Pub. Date: Dec. 26, 2024

(54) DISPLAY DEVICE

(71) Applicant: Semiconductor Energy Laboratory Co., Ltd., Atsugi-shi, Kanagawa-ken (JP)

(72) Inventors: Yuichi YANAGISAWA, Atsugi (JP); Ryota HODO, Atsugi (JP); Hiromi SAWAI, Atsugi (JP); Hideaki SHISHIDO, Atsugi (JP); Daiki NAKAMURA, Atsugi (JP)

(21) Appl. No.: 18/698,966

(22) PCT Filed: Oct. 14, 2022
(86) PCT No.: PCT/IB2022/059835

§ 371 Date: Apr. 5, 2024

(30) Foreign Application Priority Data
Oct. 27, 2021 (JP) 2021-175143

(51) Int. Cl. H10K 59/122; H10K 59/12; H10K 59/38

(52) U.S. Cl. CPC H10K 59/122; H10K 59/1201; H10K 59/38

(57) ABSTRACT

A display device that can easily achieve a higher resolution is provided. A display device with high display quality is provided. The display device includes a pixel electrode, a first organic layer, a second organic layer, a first insulating layer, a second insulating layer, and a common electrode. The first insulating layer includes a first portion in contact with part of a top surface of the pixel electrode, a second portion in contact with a side surface of the pixel electrode, and a third portion not in contact with the pixel electrode. The first organic layer includes a fourth portion in contact with another part of the top surface of the pixel electrode and a fifth portion in contact with the first portion. The second organic layer is in contact with the third portion and isolated from the first organic layer. The second insulating layer covers the fifth portion and the second organic layer and is in contact with the first insulating layer between the first organic layer and the second organic layer. The common electrode includes a portion overlapping with the fourth portion and a portion overlapping with the second organic layer with the second insulating layer therebetween. The first organic layer and the second organic layer contain the same material.

### TECHNICAL FIELD

One embodiment of the present invention relates to a display device. One embodiment of the present invention relates to a method for manufacturing a display device.

Note that one embodiment of the present invention is not limited to the above technical field. Examples of a technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, higher-resolution display panels have been required. Examples of devices that require high-resolution display panels include a smartphone, a tablet terminal, and a laptop computer. In addition, higher resolution has been required for a stationary display device such as a television device or a monitor device with an increase in definition. Furthermore, a device for virtual reality (VR) or augmented reality (AR) is given as an example of a device that is required to have the highest resolution.

In addition, examples of a display device that can be employed for a display panel include, typically, a liquid crystal display device, a light-emitting apparatus including a light-emitting element such as an organic EL (Electro Luminescence) element or a light-emitting diode (LED), electronic paper performing display by an electrophoretic method or the like, and the like.

For example, the basic structure of an organic EL element is a structure where a layer containing a light-emitting organic compound is provided between a pair of electrodes. By voltage application to this element, light emission can be obtained from the light-emitting organic compound. A display device using such an organic EL element does not need a backlight that is necessary for a liquid crystal display device or the like; thus, a thin, lightweight, high-contrast, and low-power-consumption display device can be achieved. Patent Document 1, for example, discloses an example of a display device using an organic EL element.

### REFERENCE

### Patent Document

### [Patent Document 1] Japanese Published Patent Application No. 2002-324673

### SUMMARY OF THE INVENTION

Problems to be Solved by the Invention

An object of one embodiment of the present invention is to provide a display device that can easily achieve a higher resolution. Another object is to provide a display device with high display quality. Another object is to provide a display device with high contrast. Another object is to provide a display device with high color reproducibility. Another object is to provide a display device with a high aperture ratio. Another object is to provide a highly reliable display device.

Another object of one embodiment of the present invention is to provide a display device having a novel structure or a manufacturing method of the display device. Another object of one embodiment of the present invention is to provide a method for manufacturing the above-described display device with high yield. Another object of one embodiment of the present invention is to at least reduce at least one of problems of conventional technique.

Note that the description of these objects does not preclude the existence of other objects. In one embodiment of the present invention, there is no need to achieve all these objects. Note that objects other than these can be derived from the description of the specification, the drawings, the claims, and the like.

### Means for Solving the Problems

One embodiment of the present invention is a display device including a pixel electrode, a first organic layer, a second organic layer, a first insulating layer, a second insulating layer, and a common electrode. The first insulating layer includes a first portion in contact with part of a top surface of the pixel electrode, a second portion in contact with a side surface of the pixel electrode, and a third portion not in contact with the pixel electrode. The first organic layer includes a fourth portion in contact with another part of the top surface of the pixel electrode and a fifth portion in contact with the first portion of the first insulating layer. The second organic layer is in contact with the third portion of the first insulating layer and isolated from the first organic layer. The second insulating layer covers the fifth portion of the first organic layer and the second organic layer and is in contact with the first insulating layer between the first organic layer and the second organic layer. The common electrode includes a portion overlapping with the fourth portion of the first organic layer and a portion overlapping with the second organic layer with the second insulating layer therebetween. The first organic layer and the second organic layer contain the same material.

Another embodiment of the present invention is a display device including a pixel electrode, an organic layer, a first insulating layer, a second insulating layer, and a common electrode. The first insulating layer includes a first portion in contact with part of a top surface of the pixel electrode, a second portion in contact with a side surface of the pixel electrode, and a third portion not in contact with the pixel electrode. The organic layer includes a fourth portion in contact with another part of the top surface of the pixel electrode, a fifth portion in contact with the first portion of the first insulating layer, a sixth portion in contact with the second portion of the first insulating layer, and a seventh portion in contact with the third portion of an insulating layer. The second insulating layer covers the fifth portion, the sixth portion, and the seventh portion of the organic layer. The common electrode includes a portion overlapping with the fourth portion of the organic layer and a portion overlapping with the seventh portion with the second insulating layer therebetween. The sixth portion of the organic layer includes a region where a thickness is smaller than or equal to half of that of the fourth portion.

In any of the above, a resin layer is preferably further included. The resin layer overlaps with the first insulating layer with the second insulating layer therebetween. The common electrode includes a portion positioned over the resin layer. Moreover, in that case, the resin layer preferably has a top surface with a convex shape or a concave shape.

In any of the above, it is preferable that a first coloring layer and a second coloring layer be further included and a plurality of the pixel electrodes be included. In that case, one of the pixel electrodes overlaps with the first coloring layer, and another one of the pixel electrodes overlaps with the second coloring layer.

Alternatively, in any of the above, it is preferable that a color conversion layer be further included and a plurality of the pixel electrodes be included. In that case, it is preferable that one of the pixel electrodes overlap with the color conversion layer and another one of the pixel electrodes do not overlap with the color conversion layer. Furthermore, it is preferable that a first coloring layer and a second coloring layer be included. In that case, it is preferable that the first coloring layer overlap with the one of the pixel electrodes with the color conversion layer therebetween, and the second coloring layer overlap with another one of the pixel electrodes. Moreover, the color conversion layer preferably contains a quantum dot.

Alternatively, in any of the above, it is preferable that a first color conversion layer and a second color conversion layer be included and a plurality of the pixel electrodes be included. In that case, it is preferable that one of the pixel electrodes overlap with the first color conversion layer, and another one of the pixel electrodes overlap with the second color conversion layer. Furthermore, it is preferable that a first coloring layer and a second coloring layer be included. In that case, it is preferable that the first coloring layer overlap with the one of the pixel electrodes with the first color conversion layer therebetween, and the second coloring layer overlap with another one of the pixel electrodes with the second color conversion layer therebetween.

Alternatively, in any of the above, a transistor in which a channel is formed in silicon is preferably included. In that case, the pixel electrode is preferably positioned above the transistor.

Alternatively, in any of the above, a transistor in which a channel is formed in a layer containing one or both of indium and zinc is preferably included. In that case, the pixel electrode is preferably positioned above the transistor.

Alternatively, in any of the above, it is preferable that a first transistor in which a channel is formed in silicon and a second transistor in which a channel is formed in a layer containing one or both of indium and zinc be included. In that case, it is preferable that the second transistor be positioned above the first transistor, and the pixel electrode be positioned above the second transistor.

### Effect of the Invention

According to one embodiment of the present invention, a display device that easily achieves higher resolution can be provided. Alternatively, a display device with high display quality can be provided. Alternatively, a display device with high contrast can be provided. Alternatively, a display device with high color reproducibility can be provided. Alternatively, a display device with a high aperture ratio can be provided. Alternatively, a highly reliable display device can be provided.

According to one embodiment of the present invention, a display device having a novel structure or a manufacturing method of the display device can be provided. Alternatively, a method for manufacturing the above-described display device with high yield can be provided. One embodiment of the present invention can at least reduce at least one of problems of the conventional technique.

Note that the description of these effects does not preclude the existence of other effects. One embodiment of the present invention does not necessarily have all these effects. Note that effects other than these can be derived from the description of the specification, the drawings, the claims, and the like.

### BRIEF DESCRIPTION OF THE DRAWINGS

FIG. 1A to FIG. 1C are diagrams illustrating a structure example of a display device.

FIG. 2 is a diagram illustrating a structure example of a display device.

FIG. 3 is a diagram illustrating a structure example of a display device.

FIG. 4A and FIG. 4B are diagrams illustrating structure examples of a display device.

FIG. 5A to FIG. 5C are diagrams illustrating structure examples of a display device.

FIG. 6A to FIG. 6C are diagrams illustrating structure examples of a display device.

FIG. 7A to FIG. 7G are diagrams illustrating an example of a method for manufacturing a display device.

FIG. 8A to FIG. 8E are diagrams illustrating a method for manufacturing a display device.

FIG. 9A to FIG. 9F are diagrams illustrating structure examples of pixels.

FIG. 10 is a diagram illustrating a structure example of a display device.

FIG. 11A and FIG. 11B are diagrams illustrating structure examples of a display device.

FIG. 12A and FIG. 12B are diagrams illustrating a structure example of a display device.

FIG. 13 is a diagram illustrating a structure example of a display device.

FIG. 14 is a diagram illustrating a structure example of a display device.

FIG. 15 is a diagram illustrating a structure example of a display device.

FIG. 16 is a diagram illustrating a structure example of a display device.

FIG. 17 is a diagram illustrating a structure example of a display device.

FIG. 18 is a diagram illustrating a structure example of a display device.

FIG. 19A to FIG. 19F are diagrams illustrating structure examples of a light-emitting device.

FIG. 20A to FIG. 20C are diagrams illustrating structure examples of a light-emitting device.

FIG. 21A to FIG. 21D are diagrams illustrating structure examples of electronic devices.

FIG. 22A to FIG. 22F are diagrams illustrating structure examples of electronic devices.

FIG. 23A to FIG. 23G are diagrams illustrating structure examples of electronic devices.

### MODE FOR CARRYING OUT THE INVENTION

Embodiments are described below with reference to the drawings. Note that the embodiments can be implemented with many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases. Note that in each drawing described in this specification, the size, the layer thickness, or the region of each component is exaggerated for clarity in some cases. Thus, they are not limited to the illustrated scale.

Note that in this specification and the like, ordinal numbers such as “first” and “second” are used in order to avoid confusion among components and do not limit the number.

Note that in this specification and the like, the expression “top surface shapes are substantially the same” means that at least outlines of stacked layers partly overlap with each other.

For example, the case of processing the upper layer and the lower layer with the use of the same mask pattern or mask patterns that are partly the same is included. However, in some cases, the outlines do not completely overlap with each other and the upper layer is positioned on an inner side of the lower layer or the upper layer is positioned on an outer side of the lower layer; such a case is also represented by the expression “top surface shapes are substantially the same”. Note that in this specification and the like, a top surface shape of a component means the contour shape of the component in a plan view. A plan view means that the component is observed from a normal direction of a formation surface of the component or a surface of a support (e.g., a substrate) where the component is formed.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacking order (or formation order) of a stacked body or the like is described, even in the case where a surface on which the stacked body is provided (e.g., a formation surface, a support surface, an adhesion surface, or a planar surface) is positioned above the stacked body in the drawings, the direction and the opposite direction are expressed using “under” and “over”, respectively, in some cases.

In this specification and the like, the term “film” and the term “layer” can be interchanged with each other. For example, in some cases, the term “conductive layer” and the term “insulating layer” can be interchanged with the term “conductive film” and the term “insulating film”, respectively.

### Embodiment 1

In this embodiment, a structure example of a display device of one embodiment of the present invention and an example of a method for manufacturing the display device will be described.

One embodiment of the present invention is a display device including a light-emitting element (also referred to as a light-emitting device). The display device includes two or more kinds of pixels (also referred to as subpixels) with different emission colors. Each pixel includes a white-light-emitting element and a coloring layer that colors light from the light-emitting element. Each light-emitting element includes a pair of electrodes (a pixel electrode and a common electrode) and an EL layer therebetween. The light-emitting element is preferably an organic EL element. The light-emitting elements provided in pixels with different colors include the same EL layer, and the coloring layers provided in pixels with different colors transmit light of different colors. For example, by including three kinds of coloring layers that transmit light of red (R), green (G), and blue (B) and absorb light of another color, a full-color display device can be achieved.

A display device including a white-light-emitting element and a coloring layer does not need to form EL layers separately for pixels; thus, a common film provided across all the pixels can be used as the EL layer. Thus, the manufacturing process can be simplified as compared with the case where EL layers are separately formed for pixels. Here, in the case where EL layers are separately formed, a method such as an evaporation method using a shadow mask like a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a deposited film due to vapor scattering, for example; accordingly, it is difficult to achieve the high resolution and high aperture ratio of the display device. Therefore, in the case of manufacturing a high-resolution display device, a structure using a white-light-emitting element and a coloring layer is preferably employed.

Meanwhile, when an EL layer is continuous across all the pixels, leakage current flows through the EL layer between adjacent pixels, in which case unintentional light emission occurs in some cases. For example, when a light-emitting element of a certain pixel emits light, a light-emitting element of an adjacent pixel with a different color emits light by leakage current and color mixture occurs, in which case color reproducibility of the display device might decrease. Since the distance between adjacent pixels is short particularly in the display device with high resolution, leakage current flowing through the EL layer might become too large to ignore. Particularly when the EL layer includes a low-resistance layer, leakage current might be increased.

In view of the above, one embodiment of the present invention has a structure in which the EL layer is partly thinned or divided in a self-aligned manner without use of a fine metal mask or the like. Specifically, a step shape that is large enough to divide the EL layer or form a thin portion in the EL layer is provided between two adjacent pixel electrodes. For example, a step shape having a level difference greater than half of the thickness of the EL layer is provided. In other words, a groove portion having a level difference greater than half of the thickness of the

EL layer is formed between a pair of pixel electrodes. When the EL layer is formed to cover this groove portion, the EL layer is physically divided or thinned. Then, the common electrode is formed, so that the light-emitting element is formed. This can inhibit or prevent leakage current through the EL layer without increasing the number of processes; thus, a display device with high color reproducibility and high contrast can be achieved.

Here, in the case where the EL layer includes a low-resistance layer, when the low-resistance layer is in contact with the pixel electrode, an electrical short circuit might occur between the pixel electrode and the EL layer. In view of the above, one embodiment of the present invention has a structure in which a first insulating layer (also referred to as a partition) covering an end portion (including a side surface) of the pixel electrode is provided and the insulating layer has a step shape. Thus, the EL layer can be prevented from being in contact with the side surface of the pixel electrode.

Specifically, a top surface of the first insulating layer is formed to have a concave shape. At this time, part of a surface of the first insulating layer which is in contact with the EL layer is formed to be substantially perpendicular to a substrate surface or a top surface of the pixel electrode. For example, the angle between part of a surface of the first insulating layer which is in contact with the EL layer and a substrate surface or a top surface of the pixel electrode is greater than or equal to 70° and less than or equal to 120°, preferably greater than or equal to 75° and less than or equal to 115°, further preferably greater than or equal to 80° and less than or equal to 110°. For example, the side surface of the pixel electrode is processed to be substantially perpendicular to a substrate surface or a top surface of the pixel electrode, and the first insulating layer is formed to cover the side surface of the pixel electrode, so that the first insulating layer can be manufactured. With the use of the first insulating layer, the EL layer formed over the first insulating layer has a partly thinned portion or is divided in a self-aligned manner.

For example, the EL layer includes a portion having a thickness locally smaller than that of another region in a region overlapping with the first insulating layer. Specifically, the EL layer includes a region having a thickness smaller than or equal to half, preferably smaller than or equal to 40%, further preferably smaller than or equal to 30%, and larger than 0% of the thickness of a portion overlapping with the pixel electrode in a portion overlapping with the first insulating layer. Thus, current flowing between adjacent light-emitting elements through the EL layer can be inhibited.

Furthermore, contact between a low-resistance layer included in the EL layer and the common electrode might also cause an electrical short circuit between the EL layer and the common electrode, resulting in color mixture. In view of this, one embodiment of the present invention is provided with a second insulating layer (also referred to as a protective layer) that covers an end portion of the divided EL layer or a thinned portion of the EL layer. The second insulating layer is positioned between the common electrode and an end portion of the EL layer or a thinned portion of the EL layer. Thus, contact between the common electrode and a side surface of the EL layer or a thinned portion of the EL layer can be prevented. Furthermore, for the second insulating layer, a material having a barrier property against water and oxygen is preferably used. For example, an inorganic insulating film that is less likely to diffuse water or oxygen can be used. This can inhibit degradation of the EL layer and can achieve a highly reliable display device.

Furthermore, since a groove portion is provided between two adjacent pixel electrodes, a portion covering the groove portion of the second insulating layer also has a top surface with a depressed shape (also referred to as a depressed portion). Thus, in the case where the common electrode is formed to cover the depressed portion, a phenomenon in which the common electrode is divided by a step of the depressed portion (also referred to as disconnection) might occur. In view of this, a local step of a top surface of the second insulating layer is preferably filled with a resin layer functioning as a planarization film (also referred to as LFP: Local Filling Planarization). This structure can inhibit disconnection of the common electrode and can achieve a highly reliable display device.

More specific structure examples will be described below with reference to drawings.

### [Structure Example 1]

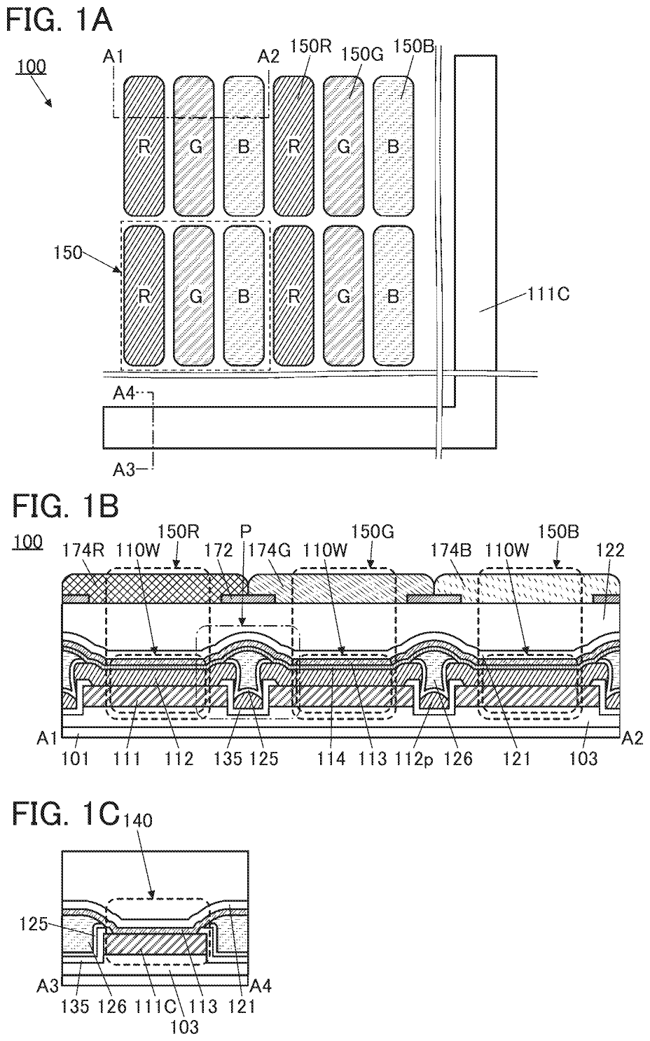

FIG. 1A illustrates a schematic top view of a display device 100. The display device 100 includes a plurality of pixels 150 arranged in a matrix. The pixel 150 includes a subpixel 150R emitting red light, a subpixel 150G emitting green light, and a subpixel 150B emitting blue light. In FIG. 1A, light-emitting regions of the subpixels are denoted by R, G, and B to easily differentiate the subpixels.

The subpixels 150R, the subpixels 150G, and the subpixels 150B are each arranged in a matrix. FIG. 1A illustrates what is called a stripe arrangement, in which subpixels of the same color are arranged in one direction. Note that the subpixel arrangement method is not limited to this, and another arrangement method such as an S-stripe arrangement, a delta arrangement, a Bayer arrangement, or a zigzag arrangement may be employed, or a PenTile arrangement, a diamond arrangement, or the like may be used.

The subpixel 150R, the subpixel 150G, and the subpixel 150B each include a light-emitting element. As the light-emitting element, an OLED (Organic Light Emitting Diode) or a QLED (Quantum-dot Light Emitting Diode) is preferably used, for example. As a light-emitting substance contained in the EL element, a substance that emits fluorescent light (a fluorescent material), a substance that emits phosphorescent light (a phosphorescent material), and a substance that exhibits thermally activated delayed fluorescence (a thermally activated delayed fluorescent (TADF) material) can be given, for example. As the light-emitting substance contained in the EL element, not only an organic compound but also an inorganic compound (a quantum dot material or the like) can be used.

FIG. 1A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the pixels 150 are arranged.

The connection electrode 111C can be provided along the outer periphery of the display region. For example, the connection electrode 111C may be provided along one side of the outer periphery of the display region, or the connection electrode 111C may be provided across two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like.

FIG. 1B and FIG. 1C are schematic cross-sectional views corresponding to the dashed-dotted line A1-A2 and the dashed-dotted line A3-A4 in FIG. 1A. FIG. 1B illustrates a schematic cross-sectional view of the subpixel 150R, the subpixel 150G, and the subpixel 150B, and FIG. 1C illustrates a schematic cross-sectional view of a connection portion 140 where the connection electrode 111C and the common electrode 113 are connected to each other.

The display device 100 includes an insulating layer 103 over a substrate 101, and a plurality of light-emitting elements 110W are provided over the insulating layer 103. A coloring layer 174R, a coloring layer 174G, and a coloring layer 174B are provided to overlap with the light-emitting elements. A light-blocking layer 172 is provided between two adjacent coloring layers.

The subpixel 150R includes the light-emitting element 110W and the coloring layer 174R. The subpixel 150G includes the light-emitting element 110W and the coloring layer 174G. The subpixel 150B includes the light-emitting element 110W and the coloring layer 174B. The light-emitting elements 110W each include a pixel electrode 111, an organic layer 112, a common layer 114, and the common electrode 113. The organic layer 112, the common layer 114, and the common electrode 113 are provided to be shared by the light-emitting elements 110W of the subpixel 150R, the subpixel 150G, and the subpixel 150B. The pixel electrode 111 is provided in each of the subpixel 150R, the subpixel 150G, and the subpixel 150B.

The organic layer 112 emits white light. For example, the organic layer 112 can contain two or more kinds of light-emitting substances. To obtain white light emission, the light-emitting substances are selected so as to emit light of complementary colors. For example, a structure containing a blue-light-emitting substance and a yellow-light-emitting substance can be given. Alternatively, a structure in which white light emission is obtained by three or more kinds of light-emitting substances may be employed, and a structure containing three kinds of light-emitting substances of red, blue, and green may be employed, for example. The organic layer 112 can also be referred to as an EL layer and includes at least a layer containing a light-emitting organic compound (a light-emitting layer).

Hereinafter, in the description common to the components that are distinguished by alphabets, such as the subpixel 150R, the subpixel 150G, and the subpixel 150B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 includes a stacked-layer structure of a hole-injection layer, a hole-transport layer, a light-emitting layer, and an electron-transport layer from the pixel electrode 111 side and the common layer 114 includes an electron-injection layer.

The pixel electrode 111 is provided for each of the light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have light-transmitting properties and the common electrode 113 has a reflective property, a bottom-emission display device can be obtained. In contrast, when the pixel electrodes have reflective properties and the common electrode 113 has a light-transmitting property, a top-emission display device can be obtained. Note that when both the pixel electrodes and the common electrode 113 have light-transmitting properties, a dual-emission display device can be also obtained.

A protective layer 121 is provided over the common electrode 113 to cover the light-emitting element 110W. The protective layer 121 has a function of preventing diffusion of impurities such as water into each light-emitting element from the above.

The protective layer 121 can have, for example, a single-layer structure or a stacked-layer structure including at least an inorganic insulating film. Examples of the inorganic insulating film include an oxide film or a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

As the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. Moreover, a top surface of the protective layer 121 is flat; therefore, when a structural object (e.g., a color filter, an electrode of a touch sensor, a lens array, or the like) is provided above the protective layer 121, the structural object can be less affected by an uneven shape caused by a lower structure.

Between two adjacent pixel electrodes 111, an insulating layer 135 that covers part of a top surface and a side surface of each of the pixel electrodes 111 is provided. The insulating layer 135 can be referred to as a partition, an embankment, or the like and has a function of defining light-emitting regions of the light-emitting elements 110W.

Here, the side surface of the pixel electrode 111 is preferably substantially perpendicular to the top surface of the pixel electrode 111 or a surface of the substrate 101. For example, the angle between the side surface of the pixel electrode 111 and the top surface of the pixel electrode 111 or the surface of the substrate 101 is greater than or equal to 70° and less than or equal to 120°, preferably greater than or equal to 75° and less than or equal to 115°, further preferably greater than or equal to 80° and less than or equal to 110°. With such a structure, part of the insulating layer 135 that covers the side surface of the pixel electrode 111 can also be substantially perpendicular to the top surface of the pixel electrode 111 or the surface of the substrate 101.

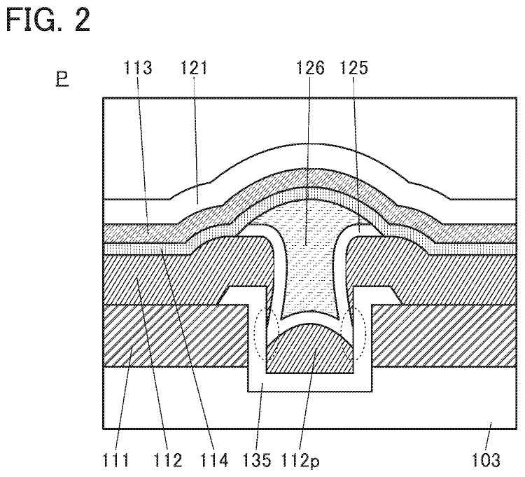

FIG. 2 illustrates an enlarged view of a region P in FIG. 1B.

The side surface of the pixel electrode 111 is processed to be substantially perpendicular to the substrate surface or the top surface of the pixel electrode 111. Note that any one of the side surfaces of a pair of pixel electrodes 111 can be processed to be substantially perpendicular to the substrate surface or the top surface of the pixel electrode 111.

Here, an example in which a region of the insulating layer 103 not overlapping with the pixel electrode 111 is thinned by etching or the like is shown. That is, the insulating layer 103 can be regarded as having a groove portion or a depressed portion.

The insulating layer 135 is provided to cover the side surfaces and part of the top surfaces of the pair of pixel electrodes 111 and a surface of the depressed portion of the insulating layer 103. A top surface of the insulating layer 135 has a concave shape in a region between the pair of pixel electrodes 111. The surface of a portion of the insulating layer 135 covering the side surface of the pixel electrode 111 preferably includes a portion where an angle formed with the substrate surface or the top surface of the pixel electrode 111 is greater than or equal to 70° and less than or equal to 120°, preferably greater than or equal to 75° and less than or equal to 115°, further preferably greater than or equal to 80° and less than or equal to 110°.

When an organic film to be the organic layer 112 is formed over the insulating layer 135 having such a shape, the organic film is divided in a self-aligned manner, so that an organic layer 112p that is over the insulating layer 135 and positioned between the organic layer 112 over the pixel electrode 111 and the pair of pixel electrodes 111 is formed.

The organic layer 112 includes a portion in contact with the top surface of the pixel electrode 111, a portion overlapping with the pixel electrode 111 with the insulating layer 135 therebetween, and a portion in contact with a sidewall of the depressed portion of the insulating layer 135. The organic layer 112p is in contact with a bottom surface and part of the side surface of the depressed portion of the insulating layer 135.

In a region overlapping with the insulating layer 135, an insulating layer 125 is provided to cover part of a top surface of the organic layer 112, a side surface of the organic layer 112, and a top surface of the organic layer 112p. The insulating layer 125 is positioned between the organic layer 112 and a resin layer 126 and functions as a protective layer for preventing contact between the resin layer 126 and the organic layer 112. When the organic layer 112 and the resin layer 126 are in contact with each other, the organic layer 112 might be dissolved by an organic solvent or the like used at the time of forming the resin layer 126. Thus, by providing the insulating layer 125, the side surface of the organic layer 112 can be protected. Furthermore, the insulating layer 125 can prevent the side surface of the organic layer 112 from being exposed to the air. Accordingly, light-emitting elements and a light-receiving element with high reliability can be manufactured.

An insulating layer containing an inorganic material can be used as the insulating layer 125. As the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed as the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 125, a sputtering method, a CVD method, a PLD method, an ALD method, or the like can be used. The insulating layer 125 is preferably formed by an ALD method achieving good coverage.

As indicated by a dashed line in FIG. 2, the organic layer 112 and the organic layer 112p are physically divided, and in a region between these, the insulating layer 135 and the insulating layer 125 are in contact with each other. Accordingly, an end portion of the organic layer 112 can be covered with the insulating layer 135 and the insulating layer 125; thus, diffusion of impurities from the end portion of the organic layer 112 can be prevented, leading to a highly reliable display device.

The resin layer 126 is provided over the insulating layer 125. The resin layer 126 is provided to fill a depressed portion of the insulating layer 125. Furthermore, over the resin layer 126, the common layer 114, the common electrode 113, and the protective layer 121 are provided. Filling the depressed portion of the insulating layer 125 by the resin layer 126 can prevent a phenomenon in which the common electrode 113 is divided by a step (such a phenomenon is also referred to as disconnection) from occurring and the common electrode 113 over the organic layer 112 from being insulated. The resin layer 126 can also be referred to as an LFP layer.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used as the resin material used for the resin layer 126. A photoresist may be used as the photosensitive resin. As the photosensitive resin, a positive photosensitive material or a negative photosensitive material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

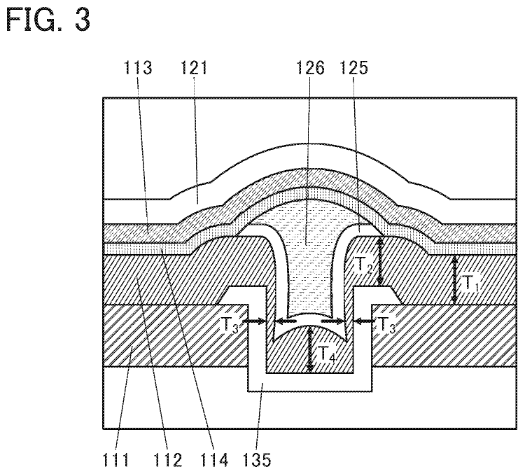

FIG. 3 illustrates an example of a case where the organic layer 112 is not divided and a thinned portion is formed in the organic layer 112. FIG. 3 illustrates a shape where the organic layer 112 and the organic layer 112p illustrated in FIG. 2 are connected.

The thickness of a portion of the organic layer 112 in contact with the top surface of the pixel electrode 111 is T₁, the thickness of a portion of the organic layer 112 that is over the insulating layer 135 and overlaps with the pixel electrode 111 is T₂, the thickness of a portion of the organic layer 112 in contact with a surface substantially perpendicular to the insulating layer 135 is T₃, and the thickness of a portion of the organic layer 112 in contact with a flat portion of the top surface of the insulating layer 135 is T₄.

Note that here, the thickness refers to not a thickness in a direction perpendicular to a reference surface such as a substrate surface but a thickness in a normal direction with respect to a formation surface. Thus, in the case where a formation surface has unevenness, the direction that defines the thickness varies depending on the place.

The thickness T₁, the thickness T₂, and the thickness T₄ are substantially equal to one another. Meanwhile, the thickness T₃ is smaller than the thickness T₁, the thickness T₂, and the thickness T₄. Specifically, the thickness T₃ is smaller than or equal to half (50%), preferably smaller than or equal to 40%, further preferably smaller than or equal to 30%, and is larger than 0% of the thickness T₁, the thickness T₂, or the thickness T₄.

When a region with a small thickness of the organic layer 112 is formed between adjacent light-emitting elements as described above, leakage current through the organic layer 112 can be reduced, so that unintentional light emission can be inhibited.

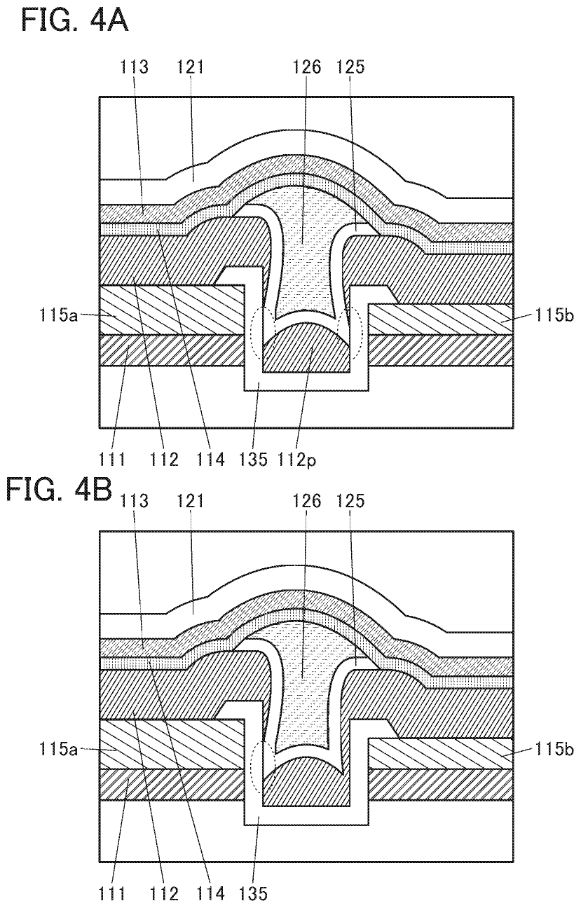

FIG. 4A illustrates an example of a case where a conductive layer 115a and a conductive layer 115b having different thicknesses and functioning as optical adjustment layers are provided over the pixel electrode 111. For each of the conductive layer 115a and the conductive layer 115b, a conductive material having a light-transmitting property is preferably used.

A film reflecting visible light is used for the pixel electrode 111 and a film having both properties of reflecting and transmitting visible light is used for the common electrode 113, whereby a microcavity structure can be obtained. At this time, by adjusting the thicknesses of the conductive layer 115a and the conductive layer 115b to obtain optimal optical path lengths, light that is intensified light with a desired wavelength can be obtained from the light-emitting element 110W even in the case where the organic layer 112 exhibiting white light emission is used.

The insulating layer 135 is provided to cover upper end portions and side surfaces of the conductive layer 115a and the conductive layer 115b. Since the conductive layer 115a and the conductive layer 115b have different thicknesses, the insulating layer 135 has different heights. That is, level difference of a step of a surface of the insulating layer 135 is different between a side where the conductive layer 115a is provided and a side where the conductive layer 115b is provided.

Here, as the level difference of a step of the surface of the insulating layer 135 is larger, the organic layer 112 is more likely to be divided, and as the level difference is smaller, the organic layer 112 tends to be connected without being divided. Thus, as illustrated in FIG. 4B, the organic layer 112 may be divided on the side with a large level difference of the step and the organic layer 112 may be connected on the side with a small level difference. Even in this case, the organic layer 112 is divided between adjacent pixels, so that leakage current through the organic layer 112 can be prevented.

Note that since the pixel electrode 111 contains a material different from those for the conductive layer 115a and the conductive layer 115b; thus, the pixel electrode and the conductive layers are formed by processing under different etching conditions in some cases. Thus, end portions of the conductive layer 115a and the conductive layer 115b may have tapered shapes.

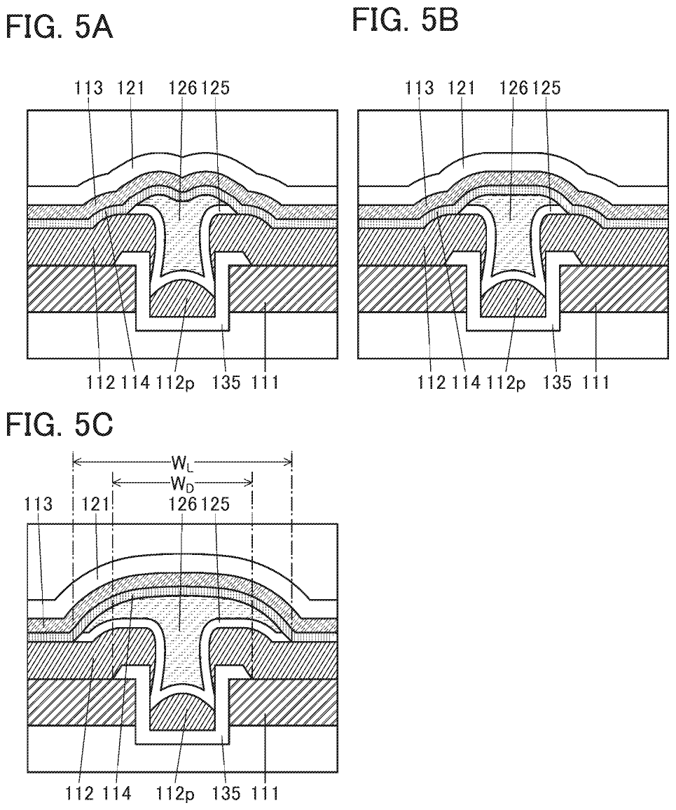

Although FIG. 2 and the like illustrate an example in which the top surface of the resin layer 126 has a gently bulged convex shape, one embodiment of the present invention is not limited thereto. For example, the top surface of the resin layer 126 only needs to be gently continuous, and at least one of a convex portion, a concave portion, and a flat portion can be included, for example. For example, FIG. 5A illustrates a schematic cross-sectional view of a case where the resin layer 126 includes a convex portion and a concave portion. FIG. 5B illustrates a schematic cross-sectional view of a case where the resin layer 126 includes a flat portion.

Here, in FIG. 2 and the like, the width of the insulating layer 135 is larger than those of the insulating layer 125 and the resin layer 126; however, one embodiment of the present invention is not limited thereto, and the width of the insulating layer 135 may be smaller than any one or both of those of the insulating layer 125 and the resin layer 126.

FIG. 5C illustrates an example of a case where a width W_{L} of the insulating layer 125 is larger than a width W_{D} of the insulating layer 135. At this time, a portion where the insulating layer 125 is positioned is a non-light-emitting region even in a region where the insulating layer 135 is not provided over the organic layer 112. With such a structure, a phenomenon in which light is emitted from a portion overlapping with the insulating layer 135 can be inhibited. Note that although FIG. 5C illustrates the case where the width of the insulating layer 125 having the structure illustrated in FIG. 2 is increased, the same can also be applied to another structure example.

In FIG. 1B, the coloring layer 174R, the coloring layer 174G, or the coloring layer 174B is provided over the light-emitting element 110W with the protective layer 121 and an insulating layer 122 therebetween. The light-blocking layer 172 is provided over the insulating layer 122. The insulating layer 122 preferably functions as a planarization layer. Thus, when the coloring layer 174 is formed over the insulating layer 122, the thickness of the coloring layer 174 can be prevented from being varied depending on the place; thus, display quality can be improved.

For example, the coloring layer 174R transmits red light, the coloring layer 174G transmits green light, and the coloring layer 174B transmits blue light. This can increase the color purity of light from each light-emitting element, so that a display device with higher display quality can be achieved. Furthermore, positional alignment of the light-emitting elements and the coloring layers is easier in the case where the coloring layers are formed over the insulating layer 122 than in the case where the coloring layers are formed on the substrate other than the substrate 101 and then the substrate 101 and the substrate are bonded to each other; accordingly, a display device with extremely high resolution can be achieved.

Note that a lens array may be provided over the coloring layer 174R, the coloring layer 174G, and the coloring layer 174B. Light emitted from the light-emitting element 110W is colored by the coloring layer and is emitted to the outside through the lens array.

FIG. 1C illustrates the connection portion 140 in which the connection electrode 111C and the common electrode 113 are electrically connected to each other. In the connection portion 140, an opening portion is provided in the insulating layer 135, the insulating layer 125, and the resin layer 126 over the connection electrode 111C. The connection electrode 111C and the common electrode 113 are electrically connected to each other in the opening portion.

Note that although FIG. 1C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin. Thus, problems do not arise in many cases even when the common layer 114 is positioned in the connection portion 140. Accordingly, the common electrode 113 and the common layer 114 can be formed using the same shielding mask, so that manufacturing cost can be reduced.

### [Structure Example 2]

A structure example of a display device whose structure is partly different from that of the above-described Structure Example 1 is described below.

### [Structure Example 2-1]

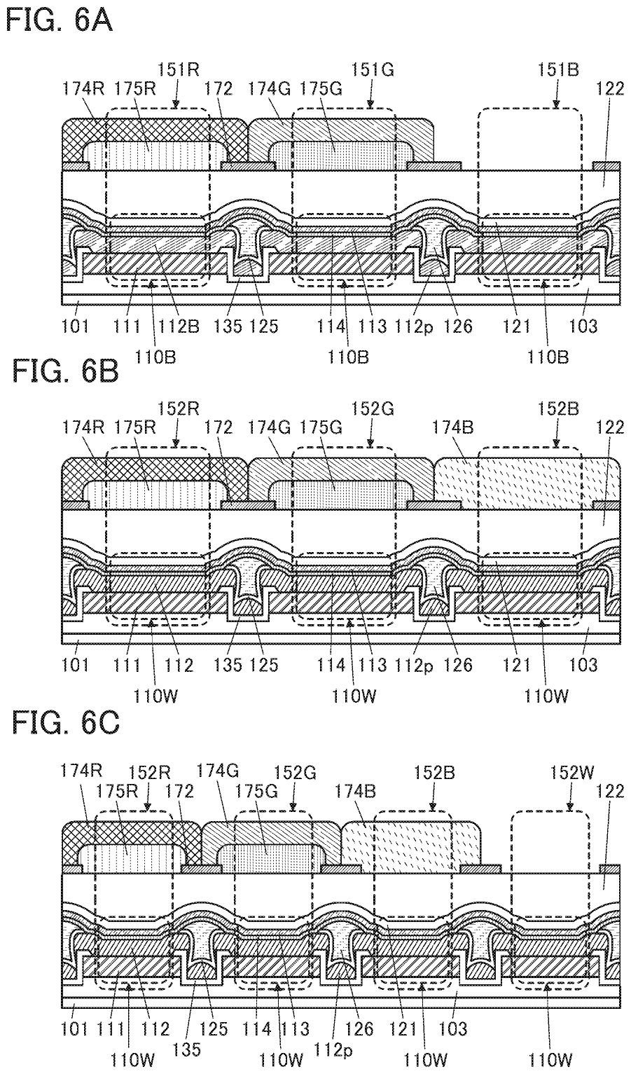

FIG. 6A illustrates a schematic cross-sectional view of a display device described below as an example. The display device includes a subpixel 151R, a subpixel 151G, and a subpixel 151B.

The subpixel 151R, the subpixel 151G, and the subpixel 151B each include a light-emitting element 110B. The light-emitting element 110B is a light-emitting element that emits blue light, violet light, or ultraviolet light, and the light-emitting element 110B includes an organic layer 112B containing a light-emitting substance that emits blue light, violet light, or ultraviolet light.

The subpixel 151R includes a color conversion layer 175R and the coloring layer 174R on an optical path of light emitted from the light-emitting element 110B. The color conversion layer 175R has a function of absorbing light emitted from the light-emitting element 110B and emitting red light.

The subpixel 151G includes a color conversion layer 175G and the coloring layer 174G on an optical path of light emitted from the light-emitting element 110B. The color conversion layer 175G has a function of absorbing light emitted from the light-emitting element 110B and emitting green light.

The subpixel 151B is provided with the light-emitting element 110B. Note that in the case where a light-emitting element emitting violet or ultraviolet light is used as the light-emitting element 110B, any one or both of a coloring layer that transmits blue light and a color conversion layer that absorbs light emitted from the light-emitting element 110B and emits blue light are preferably provided on an optical path of the light-emitting element 110B. Note that even in the case where a light-emitting element that emits blue light is used as the light-emitting element 110B, the subpixel 151B may be provided with a coloring layer that transmits blue light.

For each of the color conversion layer 175R and the color conversion layer 175G, a fluorescent material, a phosphorescent material, a resin material where quantum dots are dispersed, or the like can be used, for example.

The coloring layer 174R and the coloring layer 174G each have a function of absorbing blue or violet light that passes through the color conversion layer. Thus, color purity can be increased to achieve a display device with high display quality.

### [Structure Example 2-2]

A display device illustrated in FIG. 6B includes a subpixel 152R, a subpixel 152G, and a subpixel 152B.

The subpixel 152R includes the light-emitting element 110W, the color conversion layer 175R, and the coloring layer 174R. The light-emitting element 110W is a light-emitting element that emits white light. The color conversion layer 175R has a function of absorbing light with a wavelength shorter than that of red light among white light emitted from the light-emitting element 110W, and emitting red light. The coloring layer 174R has a function of transmitting red light and absorbing visible light of the other colors.

The subpixel 152G includes the light-emitting element 110W, the color conversion layer 175G, and the coloring layer 174G. The color conversion layer 175G has a function of absorbing light with a shorter wavelength than that of green light among white light emitted from the light-emitting element 110W, and emitting green light. The coloring layer 174G has a function of transmitting green light and absorbing visible light of the other colors.

The subpixel 152B includes the light-emitting element 110W and the coloring layer 174B. The coloring layer 174B has a function of transmitting blue light and absorbing visible light of the other colors.

When a color conversion layer is used for each of a red subpixel and a green subpixel in this manner, light that is supposed to be absorbed by the coloring layer among light emitted from a white-light-emitting element can be reused; thus, emission efficiency can be improved as compared with the structure in which the color conversion layer is not used.

As illustrated in FIG. 6C, a subpixel 152W exhibiting white may be provided.

The subpixel 152W includes the light-emitting element 110W, and a coloring layer and a color conversion layer are not provided. From the subpixel 152W, white light emitted from the light-emitting element 110W can be directly extracted. When a subpixel emitting white light is provided in this manner, power consumption can be reduced.

The above is the description of the structure examples.

### [Manufacturing Method Example]

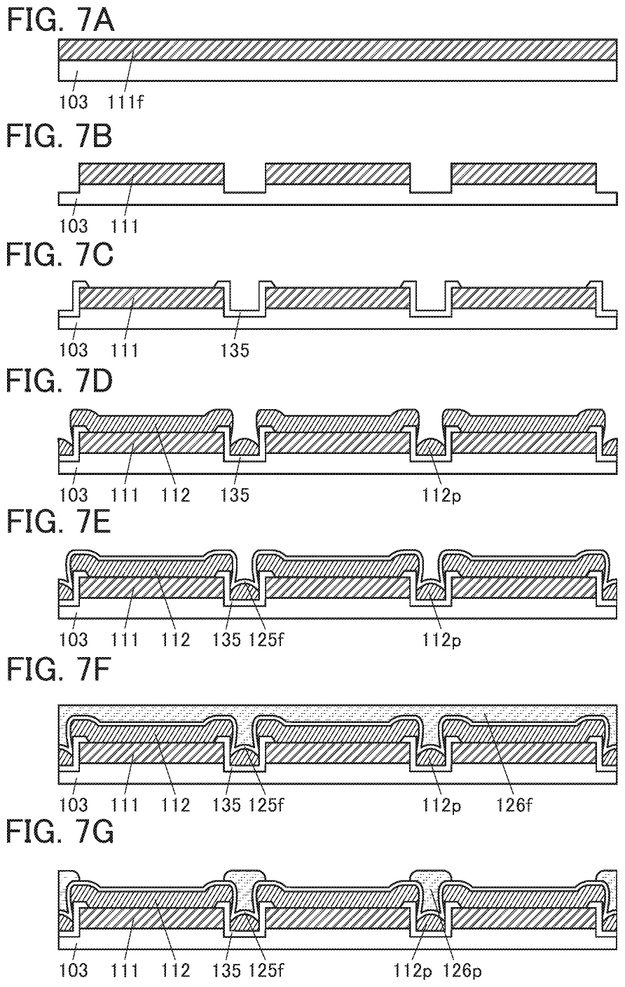

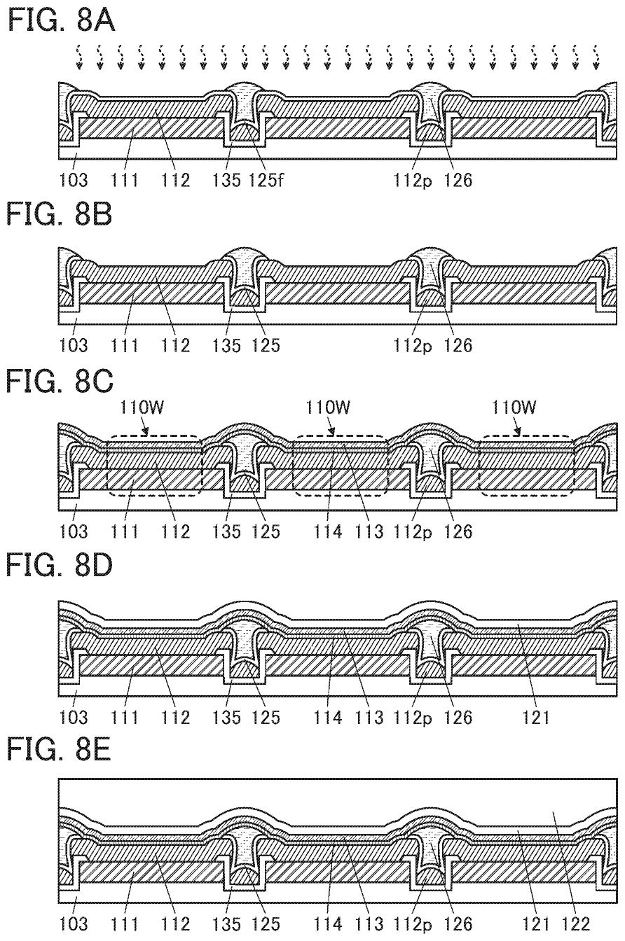

An example of a method for manufacturing the display device of one embodiment of the present invention will be described below with reference to drawings. Here, description is made using the display device 100 described in the above Structure Example 1 as an example. FIG. 7A to FIG. 8E are schematic cross-sectional views in steps of the manufacturing method of the display device described below.

Note that thin films included in the display device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

Alternatively, thin films included in the display device (insulating films, semiconductor films, conductive films, and the like) can be formed by a method such as spin coating, dipping, spray coating, ink-jetting, dispensing, screen printing, offset printing, a doctor knife method, a slit coater, a roll coater, a curtain coater, and a knife coater.

Thin films included in the display device can be processed by a photolithography method or the like. Besides, a nanoimprinting method, a sandblasting method, a lift-off method, or the like may be used for the processing of the thin films. Alternatively, island-shaped thin films may be directly formed by a film formation method using a shielding mask such as a metal mask.

There are following two typical methods of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed, for example. Alternatively, ultraviolet light, KrF laser light (wavelength: 248 nm), ArF laser light (wavelength: 193 nm), or the like can be used. Light exposure may be performed by liquid immersion light exposure technique. For light used for the light exposure, extreme ultraviolet (EUV) light with a wavelength greater than or equal to 10 nm and less than or equal to 100 nm or X-rays may be used. Furthermore, instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of thin films, a dry etching method, a wet etching method, a sandblast method, or the like can be used.

### [Preparation for Substrate 101]

As the substrate 101, a substrate having at least heat resistance high enough to withstand the following heat treatment can be used. In the case where an insulating substrate is used as the substrate 101, a glass substrate, a quartz substrate, a sapphire substrate, a ceramic substrate, an organic resin substrate, or the like can be used. Alternatively, a single crystal semiconductor substrate or a polycrystalline semiconductor substrate using silicon, silicon carbide, or the like as a material, a compound semiconductor substrate of silicon germanium or the like, or a semiconductor substrate such as an SOI substrate can be used.

As the substrate 101, it is particularly preferable to use the semiconductor substrate or the insulating substrate where a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

### [Formation of Insulating Layer 103]

Next, the insulating layer 103 is formed over the substrate 101 (not illustrated).

In the case where an inorganic insulating film is used as the insulating layer 103, the insulating layer 103 is preferably deposited by a deposition method such as a sputtering method, a CVD method, or an ALD method. For example, as the insulating layer 103, it is possible to use an oxide film or a nitride film such as a silicon oxide film, a silicon oxynitride film, a silicon nitride oxide film, a silicon nitride film, an aluminum oxide film, an aluminum oxynitride film, or a hafnium oxide film.

An organic insulating film can also be used as the insulating layer 103. For example, an organic insulating film such as an acrylic resin, a polyimide resin, an epoxy resin, a polyamide resin, a polyimide-amide resin, a siloxane resin, a benzocyclobutene-based resin, a phenol resin, or a precursor of any of these resins can be used.

As the insulating layer 103, a stacked film of an inorganic insulating film and an organic insulating film may be used. For example, a structure in which an inorganic insulating film is stacked over an organic insulating film or a structure in which an organic insulating film is stacked over an inorganic insulating film can be employed.

### [Formation of Pixel Electrode 111]

Next, a conductive film 111f to be the pixel electrode is formed over the insulating layer 103 (FIG. 7A). Then, a resist mask is formed over the conductive film 111f by photolithography method, and an unnecessary portion of the conductive film 111f is removed by etching. After that, the resist mask is removed, whereby the pixel electrode 111 can be formed (FIG. 7B).

At this time, as illustrated in FIG. 7B, a portion of the insulating layer 103 that is not covered with the pixel electrode 111 is preferably partly etched. Accordingly, a level difference between the top surface of the pixel electrode 111 and the top surface of the portion of the insulating layer 103 that is not covered with the pixel electrode 111 can be increased.

The side surface of the pixel electrode 111 is preferably processed to be perpendicular to the substrate 101 or the top surface of the pixel electrode 111 as much as possible. Alternatively, processing may be performed such that the side surface has a constricted shape. Alternatively, processing may be performed such that the upper portion has a protruding shape. For example, the pixel electrode 111 can be processed into such a shape by optimizing etching conditions by an anisotropic dry etching method, an isotropic dry etching method, a wet etching method, or the like.

In the case where a conductive film having a property of reflecting visible light is used for the pixel electrode 111, a material that has a reflectance as high as possible in the whole wavelength range of visible light (e.g., silver, aluminum, or the like) is preferably used. This can increase color reproducibility as well as light extraction efficiency of the light-emitting elements. A conductive film having a light-transmitting property may be stacked over a conductive film having a reflective property, and the thickness of the conductive film having a light-transmitting property may be different between the light-emitting elements and may be used as an optical adjustment layer. Alternatively, a structure may be employed in which an inorganic insulating layer having a light-transmitting property is formed over the pixel electrode 111 having a reflective property and a conductive layer having a light-transmitting property is formed over the inorganic insulating layer. In that case, the inorganic insulating layer is made different for each light-emitting element and can be used as an optical adjustment layer. Moreover, in that case, the pixel electrode 111 can be used for a reflective layer, and the conductive layer having a light-transmitting property over the inorganic insulating film can be used for the pixel electrode.

### [Formation of Insulating Layer 135]

Next, the insulating layer 135 that covers an upper end portion and the side surface of the pixel electrode 111 and a top surface of the insulating layer 103 is formed (FIG. 7C).

As the insulating layer 135, an inorganic insulating film or an organic insulating film can be used. The insulating layer 135 is preferably formed to have a thickness smaller than a level difference between the top surface of the pixel electrode 111 and the top surface of the portion of the insulating layer 103 that is not covered with the pixel electrode 111. Alternatively, the insulating layer 135 is preferably formed to have a thickness smaller than that of the pixel electrode 111. In particular, in the case of a display device with high resolution, the distance between the pixel electrodes is short; thus, when an insulating film to be the insulating layer 135 is thick, a groove between the pixel electrodes 111 might be filled. Therefore, in the case of a display device with high resolution (e.g., 2000 ppi or higher), an inorganic insulating film that can be easily thinned is preferably used.

The insulating layer 135 is preferably formed such that a surface of a portion covering the side surface of the pixel electrode 111 is substantially perpendicular to the surface of the pixel electrode 111 or the substrate 101. Alternatively, the surface may have a constricted shape. Alternatively, the upper portion may have a protruding shape.

### [Formation of Organic Layer 112]

Next, an organic film to be the organic layer 112 is formed over the pixel electrode 111 and the insulating layer 135 (FIG. 7D).

At this time, the insulating layer 135 has a level difference between the surface of a portion covering the top surface of the pixel electrode 111 and the surface of a portion not overlapping with the pixel electrode 111, and a portion of the insulating layer 135 covering the side surface of the pixel electrode 111 has a steep shape; thus, the formed organic film includes a partly thinned portion or is divided in a self-aligned manner. Thus, the organic layer 112 can be formed over the pixel electrode 111. In the case where the organic film is divided, the organic layer 112p is formed over the insulating layer 135.

The organic film to be the organic layer 112 includes at least a film containing a light-emitting compound. Besides, a structure where one or more of films functioning as an electron-injection layer, an electron-transport layer, a charge-generation layer, a hole-transport layer, and a hole-injection layer are stacked may be employed. The organic film can be formed by, for example, an evaporation method, a sputtering method, an inkjet method, or the like. Note that without limitation to this, the above film formation method can be used as appropriate.

[Formation of Insulating Film 125f]

Next, an insulating film 125f is formed over the organic layer 112 (FIG. 7E). The insulating film 125f is a layer to be the insulating layer 125 later. In the case where the organic layer 112 is divided, the insulating film 125f is formed to be in contact with the organic layer 112p, the insulating layer 135, and the like.

The insulating film 125f, which is formed in contact with a surface of the organic layer 112, is preferably formed by a formation method that causes less damage to the organic layer 112. In addition, the insulating film 125f is formed at a temperature lower than the upper temperature limit of the EL layer. The typical substrate temperatures in formation of the insulating film 125f and the resin layer 126 that is formed later are each lower than or equal to 200° C., preferably lower than or equal to 180° C., further preferably lower than or equal to 160° C., still further preferably lower than or equal to 150° C., yet still further preferably lower than or equal to 140° C.

As the insulating film 125f, it is particularly preferable to use a film that can be removed by a wet etching method less likely to cause damage to the organic layer 112.

An inorganic insulating film can be suitably used as the insulating film 125f. The insulating film 125f can be formed by any of a variety of deposition methods such as a sputtering method, an evaporation method, a CVD method, and an ALD method. Specifically, the insulating film 125f, which is directly formed on the organic layer 112, is preferably formed by an ALD method that gives less deposition damage to a formation layer.

In particular, for the insulating film 125f, an oxide such as aluminum oxide, hafnium oxide, or silicon oxide, a nitride such as silicon nitride or aluminum nitride, or oxynitride such as silicon oxynitride can be used. Although the film containing an inorganic insulating material can be formed by a deposition method such as a sputtering method, a CVD method, or an ALD method, an ALD method is particularly preferably used.

The thickness of the insulating film 125f is preferably larger than or equal to 3 nm, larger than or equal to 5 nm, or larger than or equal to 10 nm and smaller than or equal to 200 nm, smaller than or equal to 150 nm, smaller than or equal to 100 nm, or smaller than or equal to 50 nm.

### [Formation of Resin Layer 126]

Next, a resin film 126f is formed to cover the insulating film 125f (FIG. 7F). It is preferable to use a photosensitive organic resin for the insulating film 125f. In particular, a photosensitive acrylic resin can be used. Note that in this specification and the like, an acrylic resin refers to not only a polymethacrylic acid ester or a methacrylic resin, but also all the acrylic polymer in a broad sense in some cases.

The resin film 126f is preferably formed by a spin coating method or an ink-jet method, for example. Without limitation to this, the resin film 126f can be formed by a wet film formation method such as dipping, spray coating, dispensing, screen printing, offset printing, doctor blade coating, slit coating, roll coating, curtain coating, or knife coating, for example.

After the resin film 126f is applied, first heat treatment (also referred to as pre-baking) is preferably performed to remove a solvent or the like contained in the resin film 126f. The heat treatment is performed at a temperature lower than the upper temperature limit of the organic layer 112. The substrate temperature in heat treatment is higher than or equal to 50° C. and lower than or equal to 200° C., preferably higher than or equal to 60° C. and lower than or equal to 150° C., further preferably higher than or equal to 70° C. and lower than or equal to 120° C.

Then, the resin film 126f is subjected to light exposure with use of a photomask, so that part of the resin film 126f is irradiated with and exposed to visible light or ultraviolet light. For the resin film 126f, a positive photosensitive resin or a negative photosensitive resin can be used.

Next, development treatment is performed to remove part of the resin film 126f, whereby a patterned resin layer 126p can be formed (FIG. 7G).

Then, light irradiation for light exposure of the resin layer 126p may be performed. The irradiation of the resin layer 126p with the light can sometimes decrease the temperature required for thermal curing of the resin layer 126p. At this time, the whole substrate 101 is irradiated with the light without a photomask, so that the process can be simplified and light exposure unevenness can be inhibited.

Next, second heat treatment (also referred to as post-baking) is preferably performed to transform the resin layer 126p (FIG. 8A). In that case, the resin layer 126 after being transformed preferably has a small taper angle and the top surface with a gently curved shape as compared with the resin layer 126p before being transformed.

### [Formation of Insulating Layer 125]

Subsequently, the insulating film 125f is etched using the resin layer 126 as a mask to expose the top surface of the organic layer 112 (FIG. 8B). Accordingly, the insulating layer 125 is formed.

Although either or both of dry etching and wet etching can be employed for etching the insulating film 125f, wet etching is preferably employed for etching at the stage of exposing the organic layer 112. In particular, processing is preferably performed by only wet etching. Note that in the case of using dry etching, for example, part of the insulating film 125f is processed by dry etching and the rest is processed by wet etching, whereby etching damage to the organic layer 112 can be inhibited.

### [Formation of Common Layer 114 and Common Electrode 113]

Next, the common layer 114 is formed to cover the organic layer 112, the insulating layer 125, and the resin layer 126. The common layer 114 can be formed by a sputtering method or a vacuum evaporation method, for example.

Then, the common electrode 113 is formed to cover the common layer 114 (FIG. 8C). The common electrode 113 can be formed by either or both of a sputtering method and a vacuum evaporation method, for example.

For example, in the case where a conductive film having properties of reflecting and transmitting visible light is used for the common electrode, a stacked-layer structure of a metal or an alloy film that is thin enough to have a light-transmitting property and a conductive film having a light-transmitting property is preferable. Note that a semiconductor film having a light-transmitting property (an oxide semiconductor film) may be used instead of the conductive film having a light-transmitting property.

Each of the common layer 114 and the common electrode 113 is not necessarily formed over the entire surface of the substrate 101, and is preferably formed using a shielding mask (also referred to as a metal mask or a rough metal mask) for specifying a film formation area. It is preferable that the common layer 114 be formed in a region where the light-emitting elements are provided and the common electrode be formed in a predetermined region including a region where the light-emitting elements are provided and a region where an electrode electrically connected to the common electrode 113 is provided.

Through the above-described processes, the plurality of light-emitting elements 110W can be manufactured.

### [Formation of Protective Layer 121]

Next, the protective layer 121 is formed over the common electrode 113 (FIG. 8D). An inorganic insulating film used as the protective layer 121 is preferably formed by a sputtering method, a PECVD method, or an ALD method. In particular, an ALD method is preferable because it provides excellent step coverage and is less likely to cause a defect such as a pinhole.

### [Formation of Insulating Layer 122]

Subsequently, the insulating layer 122 is formed over the protective layer 121 (FIG. 8E). An organic insulating film or an inorganic insulating film that is thicker than the protective layer 121 can be used as the insulating layer 122. Although a spin coating method can be used for the formation of the organic insulating film, an inkjet method is preferably used because a uniform film can be formed in a desired region and thus can avoid waste of a material. In the case of using an inorganic insulating film, the top surface is preferably made flat by planarization treatment such as a CMP (Chemical Mechanical Polishing) method. When a top surface of the insulating layer 122 is made flat, variations in the thickness of the coloring layer formed over the insulating layer 122 can be reduced, leading to an increase in display quality.

### [Formation of Light-Blocking Layer 172, Coloring Layers 174R, 174G, and 174B]

Next, the light-blocking layer 172, the coloring layer 174R, the coloring layer 174G, and the coloring layer 174B are formed over the insulating layer 122. The formation order of the light-blocking layer 172 and the coloring layers is not limited thereto, and the light-blocking layer 172 may be formed first or formed later.

As the light-blocking layer 172, a metal film of titanium, chromium, or the like having low reflectance, an organic resin film impregnated with a black pigment, a black dye, or the like can be used, for example. Examples of the coloring layer 174R, the coloring layer 174G, and the coloring layer 174B include a metal material and a resin material containing a pigment or dye.

Through the above processes, the display device 100 illustrated in FIG. 1B can be manufactured.

### [Pixel Layout]

Pixel layouts different from that in FIG. 1A will be mainly described below. There is no particular limitation on the arrangement of light-emitting elements (subpixels), and a variety of methods can be employed.

Examples of a top surface shape of the subpixel include polygons such as a triangle, a quadrangle (including a rectangle and a square), and a pentagon; polygons with rounded corners; an ellipse; and a circle. Here, the top surface shape of the subpixel corresponds to a top surface shape of a light-emitting region of the light-emitting element.

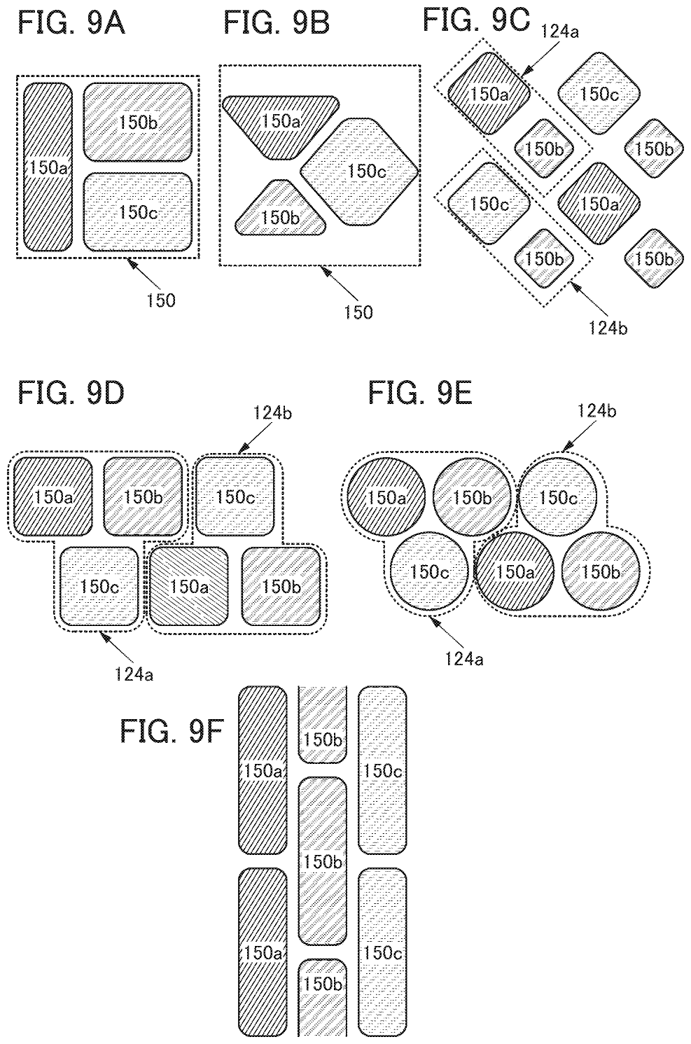

The pixel 150 illustrated in FIG. 9A employs an S-stripe arrangement. The pixel 150 illustrated in FIG. 9A is composed of three subpixels 150a, 150b, and 150c. For example, the subpixel 150a may emit blue light, the subpixel 150b may emit red light, and the subpixel 150c may emit green light.

The pixel 150 illustrated in FIG. 9B includes the subpixel 150a whose top surface has a rough trapezoidal shape with rounded corners, the subpixel 150b whose top surface has a rough triangle shape with rounded corners, and the subpixel 150c whose top surface has a rough quadrangle or rough hexagonal shape with rounded corners. The subpixel 150a has a larger light-emitting area than the subpixel 150b. In this manner, the shapes and sizes of the subpixels can be determined independently. For example, the size of a light-emitting element with higher reliability can be made smaller. For example, the subpixel 150a may emit green light, the subpixel 150b may emit red light, and the subpixel 150c may emit blue light.

Pixels 124a and 124b illustrated in FIG. 9C employ a PenTile arrangement. FIG. 9C illustrates an example where the pixels 124a including the subpixel 150a and the subpixel 150b and the pixels 124b including the subpixel 150b and the subpixel 150c are alternately arranged. For example, the subpixel 150a may emit red light, the subpixel 150b may emit green light, and the subpixel 150c may emit blue light.

The pixels 124a and 124b illustrated in FIG. 9D and FIG. 9E each employ a delta arrangement. The pixel 124a includes two subpixels (the subpixels 150a and 150b) in the upper row (first row) and one subpixel (the subpixel 150c) in the lower row (second row). The pixel 124b includes one subpixel (the subpixel 150c) in the upper row (first row) and two subpixels (the subpixels 150a and 150b) in the lower row (second row). For example, the subpixel 150a may emit red light, the subpixel 150b may emit green light, and the subpixel 150c may emit blue light.

FIG. 9D illustrates an example where each light-emitting element has a rough quadrangular top surface shape with rounded corners, and FIG. 9E is an example where each light-emitting element has a circular top surface shape.

FIG. 9F illustrates an example in which light-emitting elements of different colors are arranged in a zigzag manner. Specifically, the positions of the top sides of two subpixels arranged in the column direction (e.g., the subpixel 150a and the subpixel 150b or the subpixel 150b and the subpixel 150c) are not aligned in the top view. For example, the subpixel 150a may emit red light, the subpixel 150b may emit green light, and the subpixel 150c may emit blue light.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layouts.

At least part of this embodiment can be implemented in appropriate combination with the other embodiments described in this specification.

### Embodiment 2

In this embodiment, structure examples of a display device of one embodiment of the present invention will be described.

The display device of this embodiment can be used for, for example, display portions of a digital camera, a digital video camera, a digital photo frame, a cellular phone, a portable game machine, a smartphone, a wristwatch-type terminal, a tablet terminal, a portable information terminal, and an audio reproducing device, in addition to electronic devices with comparatively large screens, such as a television device, a desktop or laptop personal computer, a monitor for a computer or the like, digital signage, and a large game machine such as a pachinko machine.

### [Display Device 400]

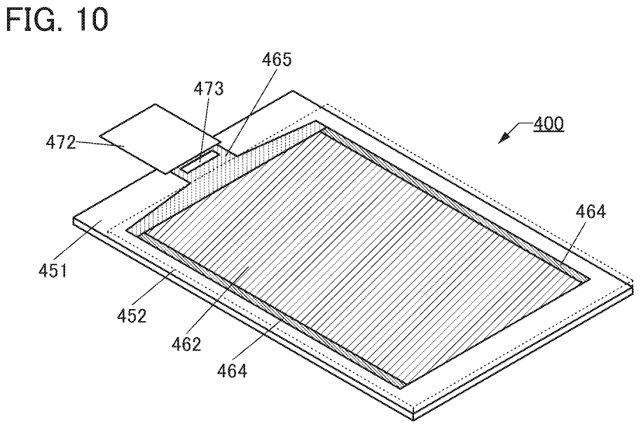

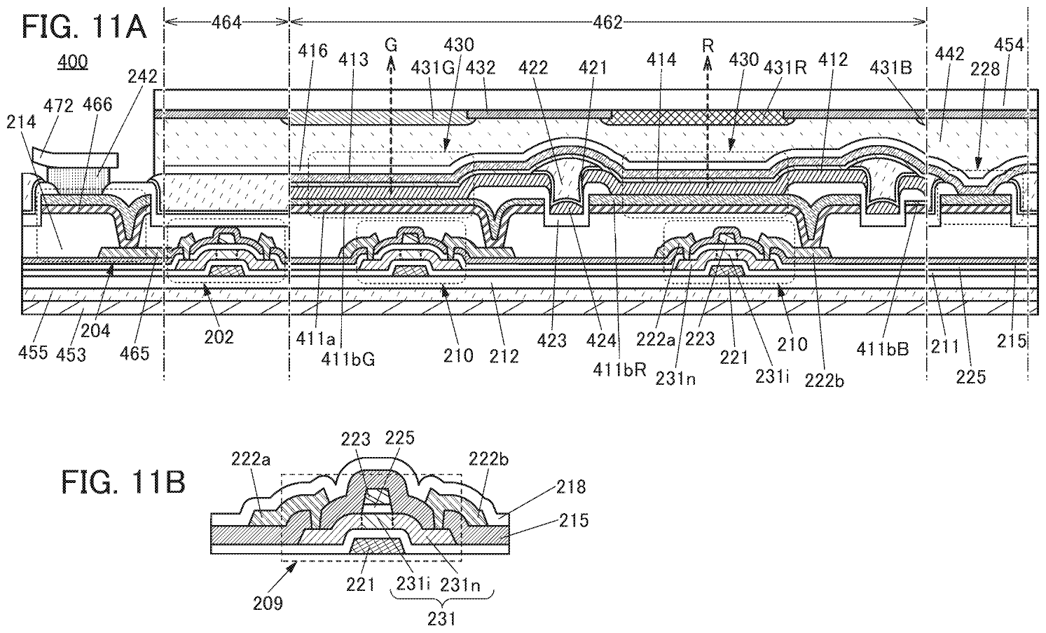

FIG. 10 illustrates a perspective view of a display device 400, and FIG. 11A illustrates a cross-sectional view of the display device 400.

The display device 400 has a structure in which a substrate 452 and a substrate 451 are bonded to each other. In FIG. 10, the substrate 452 is denoted by a dashed line.

The display device 400 includes a display portion 462, a circuit 464, a wiring 465, and the like. FIG. 10 illustrates an example in which an IC 473 and an FPC 472 are implemented on the display device 400. Thus, the structure illustrated in FIG. 10 can be regarded as a display module including the display device 400, the IC (integrated circuit), and the FPC.

As the circuit 464, a scan line driver circuit can be used, for example.

The wiring 465 has a function of supplying a signal and power to the display portion 462 and the circuit 464. The signal and power are input to the wiring 465 from the outside through the FPC 472 or input to the wiring 465 from the IC 473.

FIG. 10 illustrates an example in which the IC 473 is provided over the substrate 451 by a COG (Chip On Glass) method, a COF (Chip on Film) method, or the like. An IC including a scan line driver circuit, a signal line driver circuit, or the like can be employed as the IC 473, for example. Note that the display device 400 and the display module are not necessarily provided with an IC. In addition, the IC may be implemented on the FPC by a COF method or the like.

FIG. 11A illustrates an example of cross sections of part of a region including the FPC 472, part of the circuit 464, part of the display portion 462, and part of a region including a connection portion in the display device 400. FIG. 11A particularly illustrates an example of a cross section of the display portion 462 in a region including a green subpixel and a red subpixel.

The display device 400 illustrated in FIG. 11A includes a transistor 202, a transistor 210, a light-emitting element 430, a coloring layer 431G, a coloring layer 431R, a coloring layer 431B, and the like between a substrate 453 and a substrate 454.

For the light-emitting element 430, the coloring layer 431G, the coloring layer 431R, the coloring layer 431B, and the like, the description of the light-emitting element 110W, the coloring layer 174, and the like given in Embodiment 1 can be referred to.

Here, in the case where a pixel of the display device includes three kinds of subpixels that emit light of different colors, subpixels of three colors of red (R), green (G), and blue (B), subpixels of three colors of yellow (Y), cyan (C), and magenta (M), and the like can be given as the three subpixels. In the case where the pixel includes four subpixels, subpixels of four colors of R, G, B, and white (W), subpixels of four colors of R, G, B, and Y, and the like can be given as the four subpixels.

The substrate 454 is provided with a light-blocking layer 432, the coloring layer 431G, the coloring layer 431R, the coloring layer 431B, and the like.

The substrate 454 and a protective layer 416 are bonded to each other with an adhesive layer 442. The adhesive layer 442 is provided to overlap with the light-emitting element 430, and the display device 400 employs a solid sealing structure.

In the green subpixel, the light-emitting element 430 includes a conductive layer 411a and a conductive layer 411bG as pixel electrodes. A conductive layer 411bR is provided in the red subpixel, and a conductive layer 411bB is provided in the blue subpixel. The conductive layer 411a has a property of reflecting visible light and functions as a reflective electrode. The conductive layer 411bG, the conductive layer 411bR, and the conductive layer 411bB each have a property of transmitting visible light and function as an optical adjustment layer. FIG. 11A illustrates an example of a case where the conductive layer 411bG, the conductive layer 411bR, and the conductive layer 411bB have different thicknesses.

The conductive layer 411a is connected to a conductive layer 222b included in the transistor 210 through an opening provided in an insulating layer 214. The transistor 210 has a function of controlling driving of the light-emitting element.

An insulating layer 423 is provided to cover end portions of the pixel electrodes. Furthermore, an EL layer 412 is provided to cover the pixel electrodes and the insulating layer 423. The EL layer 412 is divided in a portion overlapping with the insulating layer 423. An organic layer 424 containing the same material as the EL layer 412 is provided over the insulating layer 423. An insulating layer 421 is provided in contact with a side surface of the EL layer 412 and a surface of the organic layer 424, and a resin layer 422 is provided to fill a depressed portion of the insulating layer 421. A common layer 414, a common electrode 413, and the protective layer 416 are provided to cover the EL layer 412, the insulating layer 421, and the resin layer 422.

Light emitted from the light-emitting element is emitted toward the substrate 454 side. For the substrate 454, a material having a high property of transmitting visible light is preferably used.

The transistor 202 and the transistor 210 are each formed over the substrate 452. These transistors can be manufactured using the same material in the same step. The substrate 453 and an insulating layer 212 are bonded to each other with an adhesive layer 455.

As a method for manufacturing the display device 400, first, a manufacture substrate provided with the insulating layer 212, the transistors, the light-emitting elements, and the like is bonded to the substrate 454 with the adhesive layer 442. Then, the substrate 453 is bonded to a surface exposed by separation of the manufacture substrate, so that the components formed over the manufacture substrate are transferred to the substrate 453. The substrate 453 and the substrate 454 each preferably have flexibility. This can increase the flexibility of the display device 400.

A connection portion 204 is provided in a region of the substrate 453 where the substrate 453 and the substrate 454 do not overlap with each other. In the connection portion 204, the wiring 465 is electrically connected to the FPC 472 through a conductive layer 466 and a connection layer 242. The conductive layer 466 can be obtained by processing the same conductive film as the pixel electrode. Thus, the connection portion 204 and the FPC 472 can be electrically connected to each other through the connection layer 242.

Each of the transistor 202 and the transistor 210 includes a conductive layer 221 functioning as a gate, an insulating layer 211 functioning as a gate insulating layer, a semiconductor layer 231 including a channel formation region 231i and a pair of low-resistance regions 231n, a conductive layer 222a connected to one of the pair of low-resistance regions 231n, the conductive layer 222b connected to the other of the pair of low-resistance regions 231n, an insulating layer 225 functioning as a gate insulating layer, a conductive layer 223 functioning as a gate, and an insulating layer 215 covering the conductive layer 223. The insulating layer 211 is positioned between the conductive layer 221 and the channel formation region 231i. The insulating layer 225 is positioned between the conductive layer 223 and the channel formation region 231i.

A conductive layer 222a and the conductive layer 222b are connected to a low-resistance regions 23 In through openings provided in the insulating layer 215. One of the conductive layer 222a and the conductive layer 222b functions as a source, and the other of the conductive layer 222a and the conductive layer 222b functions as a drain.

FIG. 11A illustrates an example in which the insulating layer 225 covers a top surface and side surfaces of the semiconductor layer. The conductive layer 222a and the conductive layer 222b are connected to the low-resistance regions 23 In through openings provided in the insulating layer 225 and the insulating layer 215.

In contrast, in a transistor 209 illustrated in FIG. 11B, the insulating layer 225 overlaps with the channel formation region 231i of the semiconductor layer 231 and does not overlap with the low-resistance regions 231n. The structure illustrated in FIG. 11B can be manufactured by processing the insulating layer 225 with the conductive layer 223 as a mask, for example. In FIG. 11B, the insulating layer 215 is provided to cover the insulating layer 225 and the conductive layer 223, and the conductive layer 222a and the conductive layer 222b are connected to the low-resistance regions 231n through openings in the insulating layer 215. Furthermore, an insulating layer 218 covering the transistor may be provided.

There is no particular limitation on the structure of the transistors included in the display device of this embodiment. For example, a planar transistor, a staggered transistor, an inverted staggered transistor, or the like can be used. In addition, either of a top-gate transistor structure and a bottom-gate transistor structure may be employed. Alternatively, gates may be provided above and below a semiconductor layer where a channel is formed.

The structure in which the semiconductor layer where a channel is formed is sandwiched between two gates is employed for the transistor 202 and the transistor 210. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity because degradation of transistor characteristics can be inhibited.

The semiconductor layer of the transistor preferably contains a metal oxide (also referred to as an oxide semiconductor). That is, a transistor using a metal oxide in its channel formation region (hereinafter an OS transistor) is preferably used for the display device of this embodiment.

The band gap of a metal oxide used for the semiconductor layer of the transistor is preferably greater than or equal to 2 eV, further preferably greater than or equal to 2.5 eV. With the use of a metal oxide having a wide bandgap, the off-state current of the OS transistor can be reduced.

A metal oxide preferably contains at least indium or zinc, and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may contain silicon. Examples of silicon include amorphous silicon and crystalline silicon (low-temperature polysilicon, single crystal silicon, or the like).

The transistor included in the circuit 464 and the transistor included in the display portion 462 may have either the same structure or different structures. A plurality of transistors included in the circuit 464 may have either the same structure or two or more kinds of structures. Similarly, a plurality of transistors included in the display portion 462 may have either the same structure or two or more kinds of structures.

A material through which impurities such as water and hydrogen do not easily diffuse is preferably used for at least one of the insulating layers covering the transistors. Thus, such an insulating layer can function as a barrier layer. Such a structure can effectively inhibit diffusion of impurities into the transistors from the outside and can increase the reliability of the display device.

An inorganic insulating film is preferably used as each of the insulating layer 211, the insulating layer 212, the insulating layer 215, the insulating layer 218, and the insulating layer 225. As the inorganic insulating film, a silicon nitride film, a silicon oxynitride film, a silicon oxide film, a silicon nitride oxide film, an aluminum oxide film, an aluminum nitride film, or the like can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above inorganic insulating films may also be used.

An organic insulating film is suitable as the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

A variety of optical members can be arranged on the inner or outer surface of the substrate 454. Examples of the optical members include a light-blocking layer, a polarizing plate, a retardation plate, a light diffusion layer (a diffusion film or the like), an anti-reflection layer, a microlens array, and a light-condensing film. Furthermore, an antistatic film inhibiting attachment of dust, a water repellent film suppressing attachment of stain, a hard coat film inhibiting generation of a scratch caused by the use, a shock absorbing layer, or the like may be provided on the outside of the substrate 454.

Providing the protective layer 416 that covers the light-emitting element can inhibit entry of impurities such as water into the light-emitting element, so that the reliability of the light-emitting element can be increased.

FIG. 11A illustrates a connection portion 228. In the connection portion 228, the common electrode 413 is electrically connected to a wiring. FIG. 11A illustrates an example of a case where the wiring has the same stacked-layer structure as the pixel electrode.

For each of the substrate 453 and the substrate 454, glass, quartz, ceramics, sapphire, a resin, a metal, an alloy, a semiconductor, or the like can be used. For the substrate on the side from which light from the light-emitting element is extracted, a material that transmits the light is used. When a flexible material is used for the substrate 453 and the substrate 454, the flexibility of the display device can be increased. Furthermore, a polarizing plate may be used as the substrate 453 or the substrate 454.

For each of the substrate 453 and the substrate 454, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (nylon, aramid, or the like), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used for one or both of the substrate 453 and the substrate 454.

For the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. Alternatively, an adhesive sheet or the like may be used.

As the connection layer 242, an anisotropic conductive film (ACF), an anisotropic conductive paste (ACP), or the like can be used.

As materials that can be used for conductive layers such as a variety of wirings and electrodes that constitute the display device, in addition to a gate, a source, and a drain of a transistor, a metal such as aluminum, titanium, chromium, nickel, copper, yttrium, zirconium, molybdenum, silver, tantalum, or tungsten, an alloy containing the metal as its main component, and the like can be given. A film containing these materials can be used in a single layer or as a stacked-layer structure.

In addition, as a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the material is preferably made thin enough to have a light-transmitting property. Furthermore, a stacked film of the above materials can be used as a conductive layer. For example, a stacked film of indium tin oxide and an alloy of silver and magnesium, or the like is preferably used because conductivity can be increased. They can be also used as conductive layers such as a variety of wirings and electrodes that constitute the display device, and conductive layers (conductive layers functioning as a pixel electrode and a common electrode) included in the light-emitting element.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

At least part of this embodiment can be implemented in appropriate combination with the other embodiments described in this specification.

### Embodiment 3

In this embodiment, a display panel of one embodiment of the present invention will be described with reference to drawings.

Display panels in this embodiment can be high-resolution display panels. For example, display devices of one embodiment of the present invention can be used for display portions of information terminal devices (wearable devices) such as wristwatch-type and bracelet-type information terminal devices and display portions of wearable devices that can be worn on a head, such as VR devices like head-mounted displays and glasses-type AR devices.

### [Display Module]

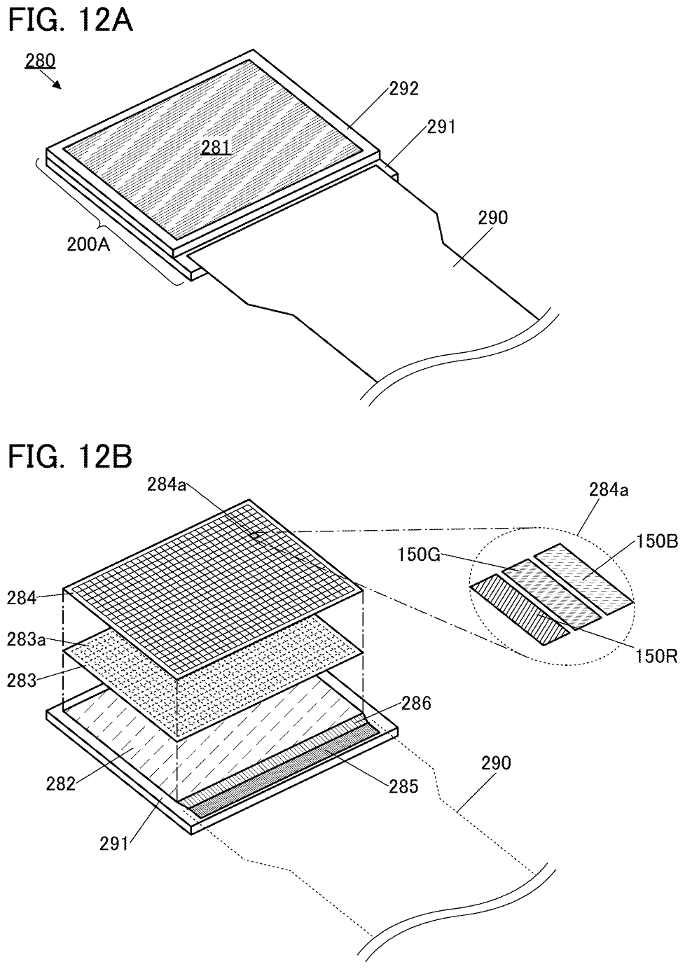

FIG. 12A illustrates a perspective view of a display module 280. The display module 280 includes a display device 200A and an FPC 290. Note that a display panel included in the display module 280 is not limited to the display device 200A and may be any of a display device 200B to a display device 200F described later.

The display module 280 includes a substrate 291 and a substrate 292. The display module 280 includes a display portion 281. The display portion 281 is a region where an image is displayed.

FIG. 12B illustrates a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. In addition, a terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 12B. The pixel 284a includes the subpixel 150R emitting red light, the subpixel 150G emitting green light, and the subpixel 150B emitting blue light.

The pixel circuit portion 283 includes a plurality of pixel circuits 283a arranged periodically. One pixel circuit 283a is a circuit for controlling light emission of three light-emitting devices included in one pixel 284a. One pixel circuit 283a may be provided with three circuits for controlling light emission of one light-emitting device. For example, the pixel circuit 283a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may further include at least one of an arithmetic circuit, a memory circuit, a power supply circuit, and the like. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. In addition, an IC may be mounted on the FPC 290.

The display module 280 can have a structure in which one or both of the pixel circuit portion 283 and the circuit portion 282 are provided to be stacked below the pixel portion 284; thus, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

The display module 280 has extremely high resolution, and thus can be suitably used for a VR device such as a head-mounted display or a glasses-type AR device. For example, even in the case of a structure in which the display portion of the display module 280 is seen through a lens, pixels of the extremely-high-resolution display portion 281 included in the display module 280 are not seen even when the display portion is enlarged by the lens, so that display providing a high sense of immersion can be performed. Without being limited thereto, the display module 280 can be also suitably used for an electronic device having a comparatively small display portion. For example, the display module 280 can be suitably used for a display portion of a wearable electronic device, such as a wristwatch.

### [Display Device 200A]

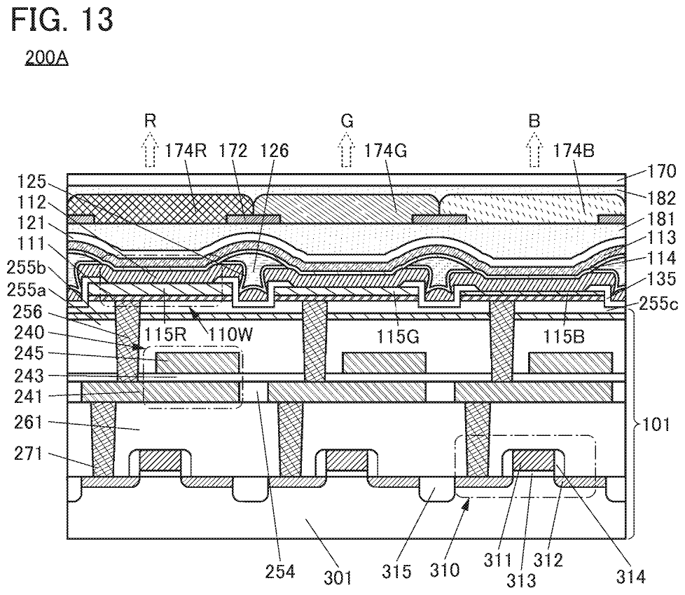

The display device 200A illustrated in FIG. 13 includes a substrate 301, the light-emitting element 110W, the coloring layer 174R, the coloring layer 174G, the coloring layer 174B, capacitors 240, and transistors 310.

The substrate 301 corresponds to the substrate 291 in FIG. 12A and FIG. 12B.

The transistor 310 is a transistor that includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and insulating layers 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layers 314 are provided to cover side surfaces of the conductive layer 311.

In addition, an element isolation layer 315 is provided between two adjacent transistors 310 to be embedded in the substrate 301.

Furthermore, an insulating layer 261 is provided to cover the transistors 310, and the capacitors 240 are provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapped with the conductive layer 241 with the insulating layer 243 therebetween.

An insulating layer 255a is provided to cover the capacitor 240, an insulating layer 255b is provided over the insulating layer 255a, and an insulating layer 255c is provided over the insulating layer 255b.

An inorganic insulating film can be suitably used as each of the insulating layer 255a, the insulating layer 255b, and the insulating layer 255c. For example, it is preferable that a silicon oxide film be used as each of the insulating layer 255a and the insulating layer 255c and that a silicon nitride film be used as the insulating layer 255b. This enables the insulating layer 255b to function as an etching protective film. Although this embodiment shows an example in which the insulating layer 255c is partly etched and a depressed portion is formed, the depressed portion is not necessarily provided in the insulating layer 255c.

The light-emitting element 110W, the insulating layer 135, the insulating layer 125, the resin layer 126, and the like are provided over the insulating layer 255c. Embodiment 1 can be referred to for structures of the light-emitting element 110W, the insulating layer 135, the insulating layer 125, and the resin layer 126.

In the display device 200A, the organic layers 112 are isolated from each other between the light-emitting elements or have a thin portion between the light-emitting elements; thus, occurrence of crosstalk between adjacent subpixels can be inhibited even in a high-resolution display panel. Accordingly, the display panel can have high resolution and high display quality.

In a region between adjacent light-emitting elements, the insulating layer 135, the insulating layer 125, and the resin layer 126 are provided.

The pixel electrode 111 of the light-emitting element is electrically connected to one of the source and the drain of the transistor 310 through a plug 256 that is embedded in the insulating layer 255a, the insulating layer 255b, and the insulating layer 255c, the conductive layer 241 that is embedded in the insulating layer 254, and the plug 271 that is embedded in the insulating layer 261. A top surface of the insulating layer 255c and a top surface of the plug 256 are level with or substantially level with each other. A variety of conductive materials can be used for the plugs.

The protective layer 121 is provided over the light-emitting element 110W. An insulating layer 181 functioning as a planarization layer is provided over the protective layer 121, and the coloring layer 174R, the coloring layer 174G, the coloring layer 174B, and the light-blocking layer 172 are provided over the insulating layer 181. A substrate 170 is bonded onto the coloring layers with an adhesive layer 182.

### [Display Device 200B]

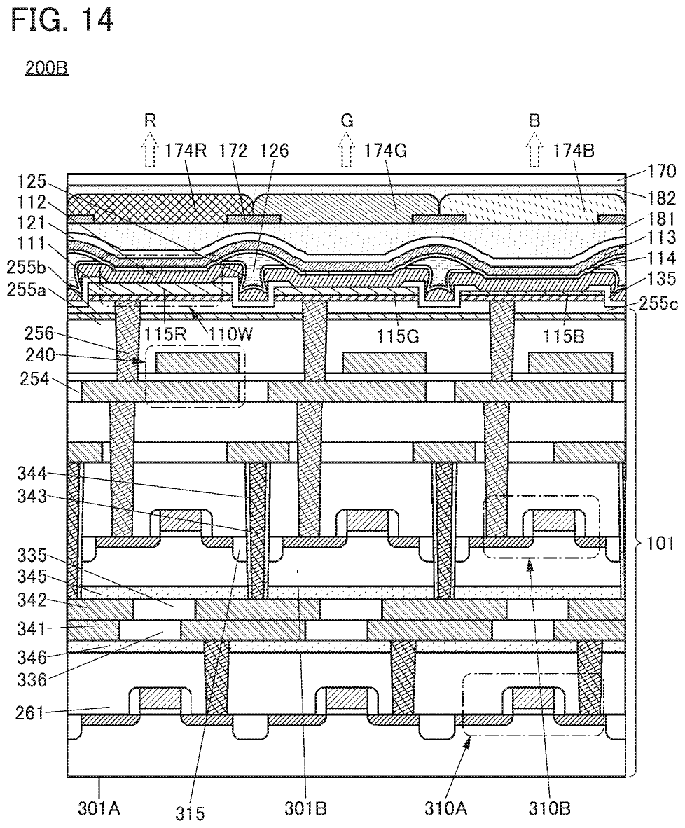

The display device 200B illustrated in FIG. 14 has a structure where transistors 310A and transistors 310B in each of which a channel is formed in a semiconductor substrate are stacked. Note that in the following description of the display panel, the description of portions similar to those of the above display panel is omitted in some cases.

The display device 200B has a structure where a substrate 301B provided with the transistors 310B, the capacitors 240, and the light-emitting devices is bonded to a substrate 301A provided with the transistors 310A.

Here, an insulating layer 345 is provided on a bottom surface of the substrate 301B, and an insulating layer 346 is provided over the insulating layer 261 provided over the substrate 301A. The insulating layers 345 and 346 are insulating layers functioning as protective layers and can inhibit diffusion of impurities into the substrate 301B and the substrate 301A. As the insulating layers 345 and 346, an inorganic insulating film that can be used as the protective layer 121 or an insulating layer 332 can be used.

The substrate 301B is provided with plugs 343 that penetrate the substrate 301B and the insulating layer 345. Here, insulating layers 344 each functioning as a protective layer are preferably provided to cover side surfaces of the plugs 343.

In addition, a conductive layer 342 is provided under the insulating layer 345 on the substrate 301B. The conductive layer 342 is embedded in an insulating layer 335, and bottom surfaces of the conductive layer 342 and the insulating layer 335 are planarized. Furthermore, the conductive layer 342 is electrically connected to the plug 343.

In contrast, a conductive layer 341 is provided over the insulating layer 346 over the substrate 301A. The conductive layer 341 is embedded in an insulating layer 336, and top surfaces of the conductive layer 341 and the insulating layer 336 are planarized.

The same conductive material is preferably used for the conductive layer 341 and the conductive layer 342. A metal film containing an element selected from Al, Cr, Cu, Ta, Ti, Mo, and W, a metal nitride film containing the above element as a component (a titanium nitride film, a molybdenum nitride film, or a tungsten nitride film), or the like can be used, for example. Copper is particularly preferably used for the conductive layer 341 and the conductive layer 342. Accordingly, it is possible to employ a Cu-to-Cu (copper-to-copper) direct bonding technique (a technique for achieving electrical continuity by connecting Cu (copper) pads to each other).

### [Display Device 200C]

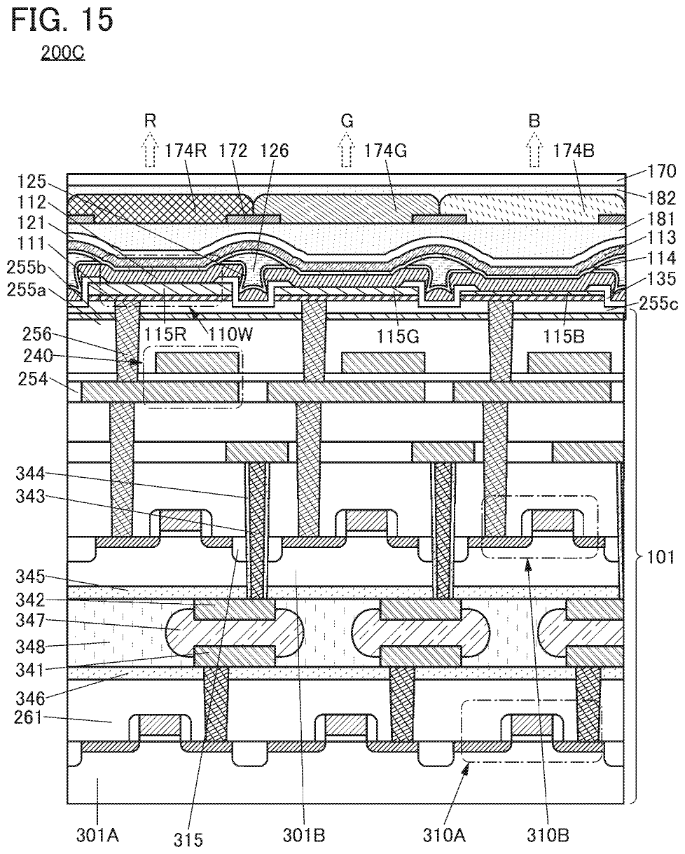

The display device 200C illustrated in FIG. 15 has a structure where the conductive layer 341 and the conductive layer 342 are bonded to each other through a bump 347.

As illustrated in FIG. 15, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder is used for the bump 347 in some cases. In addition, an adhesive layer 348 may be provided between the insulating layer 345 and the insulating layer 346. Furthermore, in the case where the bump 347 is provided, a structure without the insulating layer 335 and the insulating layer 336 may be employed.

### [Display Device 200D]

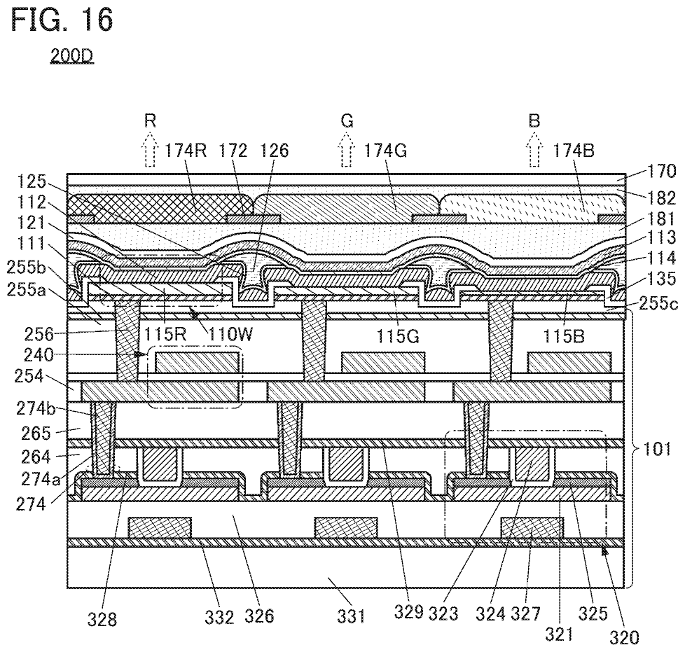

The display device 200D illustrated in FIG. 16 differs from the display device 200A mainly in a transistor structure.

A transistor 320 is a transistor (an OS transistor) in which a metal oxide (also referred to as an oxide semiconductor) is employed in a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 12A and FIG. 12B.

The insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least part of the insulating layer 326 that is in contact with the semiconductor layer 321. A top surface of the insulating layer 326 is preferably planarized.

The semiconductor layer 321 is provided over the insulating layer 326. The semiconductor layer 321 preferably includes a metal oxide (also referred to as an oxide semiconductor) film exhibiting semiconductor characteristics. The pair of conductive layers 325 is provided on and in contact with the semiconductor layer 321, and functions as a source electrode and a drain electrode.

An insulating layer 328 is provided to cover top surfaces and side surfaces of the pair of conductive layers 325, side surfaces of the semiconductor layer 321, and the like, and an insulating layer 264 is provided over the insulating layer 328. The insulating layer 328 functions as a barrier layer that prevents diffusion of impurities such as water or hydrogen from the insulating layer 264 or the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The conductive layer 324 and the insulating layer 323 that is in contact with a top surface of the semiconductor layer 321 are embedded in the opening. The conductive layer 324 functions as a second gate electrode, and the insulating layer 323 functions as a second gate insulating layer.

A top surface of the conductive layer 324, a top surface of the insulating layer 323, and a top surface of the insulating layer 264 are subjected to planarization treatment so that they are level with or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 or the like to the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers side surfaces of openings in the insulating layer 265, the insulating layer 329, the insulating layer 264, and the insulating layer 328 and part of a top surface of the conductive layer 325, and a conductive layer 274b in contact with a top surface of the conductive layer 274a. In that case, a conductive material in which hydrogen and oxygen are less likely to diffuse is preferably used for the conductive layer 274a.

### [Display Device 200E]

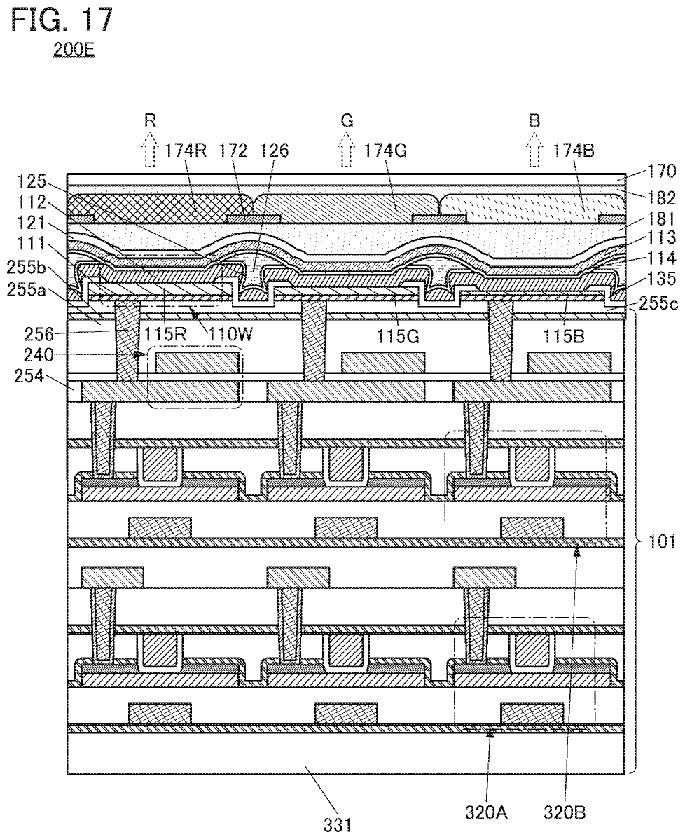

The display device 200E illustrated in FIG. 17 has a structure in which a transistor 320A and a transistor 320B each including an oxide semiconductor in a semiconductor where a channel is formed are stacked.

The display device 200D can be referred to for the structure of the transistor 320A, the transistor 320B, and other peripheral structures.

Note that although the structure in which two transistors including an oxide semiconductor are stacked is described here, the present invention is not limited thereto. For example, a structure may be employed in which three or more transistors are stacked.

### [Display Device 200F]

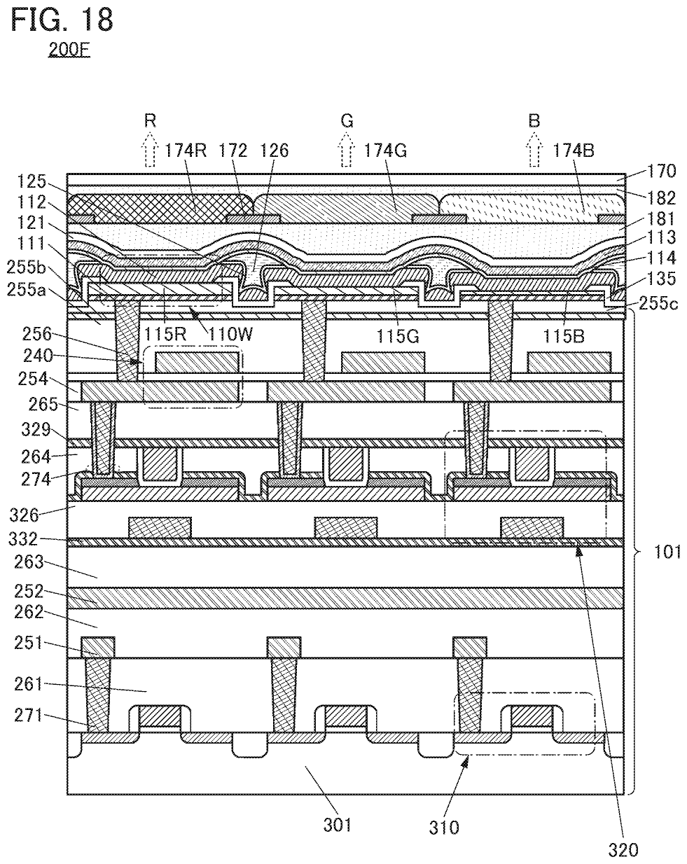

The display device 200F illustrated in FIG. 18 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. In addition, an insulating layer 262 is provided to cover the conductive layer 251, and a conductive layer 252 is provided over the insulating layer 262. The conductive layer 251 and the conductive layer 252 each function as a wiring. Furthermore, an insulating layer 263 and the insulating layer 332 are provided to cover the conductive layer 252, and the transistor 320 is provided over the insulating layer 332. Moreover, the insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel circuit. In addition, the transistor 310 can be used as a transistor included in a pixel circuit or a transistor included in a driver circuit (a gate line driver circuit or a source line driver circuit) for driving the pixel circuit. Furthermore, the transistor 310 and the transistor 320 can be used as transistors included in a variety of circuits such as an arithmetic circuit or a memory circuit.

With such a structure, not only the pixel circuit but also the driver circuit and the like can be formed directly under the light-emitting devices; thus, the display panel can be downsized as compared with the case where the driver circuit is provided around a display region.

At least part of this embodiment can be implemented in appropriate combination with the other embodiments described in this specification.

### Embodiment 4

In this embodiment, a light-emitting element (also referred to as a light-emitting device) that can be used in the display device of one embodiment of the present invention will be described.

In this specification and the like, a light-emitting device (also referred to as a light-emitting element) includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a device formed using a metal mask or an FMM (a fine metal mask or a high-resolution metal mask) may be referred to as a device having an MM (metal mask) structure. In this specification and the like, a device formed without using a metal mask or an FMM may be referred to as a device having an MML (metal maskless) structure.

In this specification and the like, a structure where light-emitting layers in light-emitting devices of different colors (here, blue (B), green (G), and red (R)) are separately formed or separately patterned is sometimes referred to as an SBS (Side By Side) structure. The SBS structure can optimize materials and structures of light-emitting devices and thus can extend the freedom of choice of materials and structures, whereby the luminance and the reliability can be easily improved. In this specification and the like, a light-emitting device capable of emitting white light may be referred to as a white-light-emitting device. Note that a combination of white-light-emitting devices with coloring layers (e.g., color filters) enables a full-color display device.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from one another on the basis of the cross-sectional shape, properties, or the like in some cases. One layer may have two or three functions of the carrier-injection layer, the carrier-transport layer, and the carrier-blocking layer in some cases.

### [Light-Emitting Device]

Structures of light-emitting devices can be classified roughly into a single structure and a tandem structure. A device with a single structure includes one light-emitting unit between a pair of electrodes. The light-emitting unit includes one or more light-emitting layers. To obtain white light emission with a single structure, two or more light-emitting layers are selected so that a white color can be produced by light emission of the light-emitting layers. For example, when two colors are used, by making the emission color of a first light-emitting layer and the emission color of a second light-emitting layer complementary colors, the light-emitting device can be configured to emit white light as a whole. To obtain white light emission by using three or more light-emitting layers, the light-emitting device is configured to emit white light as a whole by combining emission colors of the three or more light-emitting layers.

A light-emitting device with a tandem structure includes a plurality of light-emitting units between a pair of electrodes. Each light-emitting unit includes one or more light-emitting layers. When light-emitting layers that emit light of the same color are used in each light-emitting unit, luminance per predetermined current can be increased, and the light-emitting device can have higher reliability than that with a single structure. To obtain white light emission with a tandem structure, the structure is made so that light from light-emitting layers of the plurality of light-emitting units can be combined to be white light. Note that a combination of emission colors for obtaining white light emission is similar to that in the case of a single structure. In the device with a tandem structure, an intermediate layer such as a charge-generation layer is suitably provided between the plurality of light-emitting units.

When a white-light-emitting device and a light-emitting device with an SBS structure are compared with each other, the light-emitting device with the SBS structure can have lower power consumption than the white-light-emitting device. Meanwhile, the white-light-emitting device can achieve lower manufacturing cost and a higher manufacturing yield because the manufacturing process of the white-light-emitting device is simpler than that of the light-emitting device with the SBS structure.

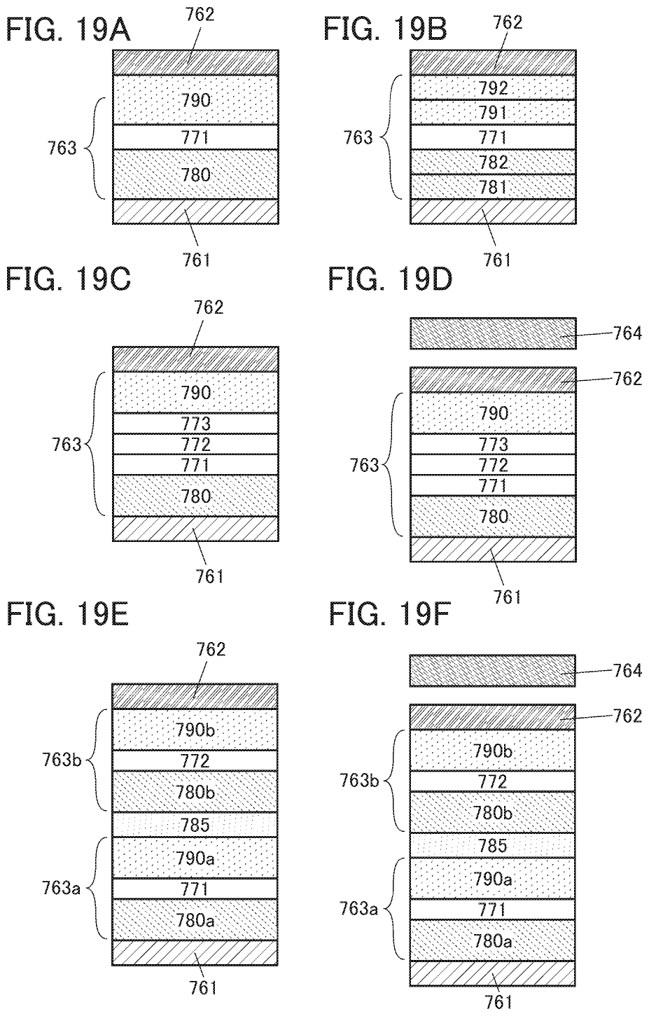

As illustrated in FIG. 19A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layer 780 and the layer 790 are replaced with each other.

The structure including the layer 780, the light-emitting layer 771, and the layer 790, which is provided between the pair of electrodes, can function as a single light-emitting unit, and the structure in FIG. 19A is referred to as a single structure in this specification.

FIG. 19B is a variation example of the EL layer 763 included in the light-emitting device illustrated in FIG. 19A. Specifically, the light-emitting device illustrated in FIG. 19B includes the lower electrode 761, a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (the light-emitting layer 771, a light-emitting layer 772, and a light-emitting layer 773) are provided between the layer 780 and the layer 790 as illustrated in FIG. 19C and FIG. 19D are other variations of the single structure. Although FIG. 19C and FIG. 19D illustrate the examples where three light-emitting layers are included, the light-emitting layer in the light-emitting device with a single structure may include two or four or more light-emitting layers.

In addition, the light-emitting device with a single structure may include a buffer layer between two light-emitting layers.

A structure where a plurality of light-emitting units (a light-emitting unit 763a and a light-emitting unit 763b) are connected in series with a charge-generation layer 785 (also referred to as an intermediate layer) therebetween as illustrated in FIG. 19E and FIG. 19F is referred to as a tandem structure in this specification. Note that a tandem structure may be referred to as a stack structure. The tandem structure enables a light-emitting device capable of high-luminance light emission. Furthermore, the tandem structure can reduce the amount of current needed for obtaining the same luminance as compared with a single structure, and thus can improve the reliability.

Note that FIG. 19D and FIG. 19F illustrate examples where the display device includes a layer 764 overlapping with the light-emitting device. FIG. 19D illustrates an example where the layer 764 overlaps with the light-emitting device illustrated in FIG. 19C, and FIG. 19F illustrates an example where the layer 764 overlaps with the light-emitting device illustrated in FIG. 19E. In FIG. 19D and FIG. 19F, a conductive film transmitting visible light is used for the upper electrode 762 to extract light to the upper electrode 762 side.

One or both of a color conversion layer and a color filter (a coloring layer) can be used as the layer 764.

In FIG. 19C and FIG. 19D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 19D, blue light emitted from the light-emitting device can be converted into light with a longer wavelength, and red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIG. 19C and FIG. 19D, light-emitting substances that emit light of different colors may be used for the light-emitting layer 771, the light-emitting layer 772, and the light-emitting layer 773. White light can be obtained when the light-emitting layer 771, the light-emitting layer 772, and the light-emitting layer 773 emit light of complementary colors. The light-emitting device with a single structure preferably includes a light-emitting layer containing a light-emitting substance emitting blue light and a light-emitting layer containing a light-emitting substance emitting visible light with a longer wavelength than blue light, for example.

A color filter may be provided as the layer 764 illustrated in FIG. 19D. When white light passes through the color filter, light of a desired color can be obtained.

In the case where the light-emitting device with a single structure includes three light-emitting layers, for example, a light-emitting layer containing a light-emitting substance emitting red (R) light, a light-emitting layer containing a light-emitting substance emitting green (G) light, and a light-emitting layer containing a light-emitting substance emitting blue (B) light are preferably included. The stacking order of the light-emitting layers can be RGB from an anode side or RBG from an anode side, for example. In that case, a buffer layer may be provided between R and G or between R and B.

For example, in the case where the light-emitting device with a single structure includes two light-emitting layers, the light-emitting device preferably includes a light-emitting layer containing a light-emitting substance that emits blue (B) light and a light-emitting layer containing a light-emitting substance that emits yellow (Y) light. Such a structure may be referred to as a BY single structure.

The light-emitting device that emits white light preferably contains two or more kinds of light-emitting substances. To obtain white light emission, two or more light-emitting substances may be selected such that their emission colors are complementary colors. For example, when an emission color of a first light-emitting layer and an emission color of a second light-emitting layer are complementary colors, the light-emitting device can be configured to emit white light as a whole. The same applies to a light-emitting device including three or more light-emitting layers.

Also in FIG. 19C and FIG. 19D, the layer 780 and the layer 790 may each independently have a stacked-layer structure of two or more layers as illustrated in FIG. 19B.

In FIG. 19E and FIG. 19F, light-emitting substances that emit light of the same color, or moreover, the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In the subpixel that emits blue light, blue light emitted from the light-emitting device can be extracted. In the subpixel that emits red light and the subpixel that emits green light, by providing a color conversion layer as the layer 764 illustrated in FIG. 19F, blue light emitted from the light-emitting device can be converted into light with a longer wavelength, and red light or green light can be extracted. As the layer 764, both a color conversion layer and a coloring layer are preferably used.

In FIG. 19E and FIG. 19F, light-emitting substances of different emission colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 19F. When white light passes through the color filter, light of a desired color can be obtained.

Although FIG. 19E and FIG. 19F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 19E and FIG. 19F illustrate the light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 19E and FIG. 19F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are replaced with each other, and the structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 771 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 771 and the hole-transport layer.

In the case of manufacturing a light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

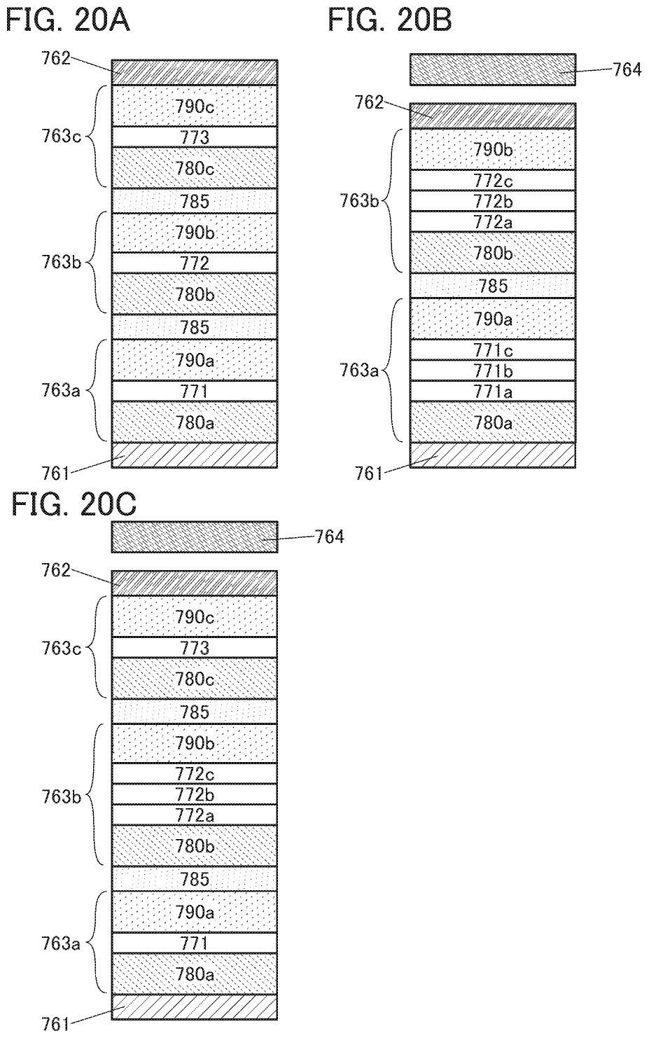

Structures illustrated in FIG. 20A to FIG. 20C can be given as examples of the light-emitting device with a tandem structure.

FIG. 20A illustrates a structure including three light-emitting units. In FIG. 20A, a plurality of light-emitting units (the light-emitting unit 763a, the light-emitting unit 763b, and a light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 20A, the light-emitting layer 771, the light-emitting layer 772, and the light-emitting layer 773 can contain light-emitting substances that emit light of the same color. Specifically, the light-emitting layer 771, the light-emitting layer 772, and the light-emitting layer 773 can each have a structure containing a blue (B) light-emitting substance (i.e., a three-unit tandem structure of B\B\B). Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 20A, light-emitting substances with different emission colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting device with a tandem structure may be employed in which light-emitting units each including a plurality of light-emitting layers are stacked as illustrated in FIG. 20B. FIG. 20B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 20B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c so that their emission colors are complementary colors. That is, the structure illustrated in FIG. 20B is a two-unit tandem structure of W\W. Note that there is no particular limitation on the stacking order of the light-emitting substances having complementary emission colors. The practitioner can select the optimal stacking order as appropriate. Although not illustrated, a three-unit tandem structure of W\W\W or a tandem structure with four or more units may be employed.

In the case where the light-emitting device with a tandem structure is used, the following structure can be given: a B\Y or Y\B two-unit tandem structure including a light-emitting unit that emits yellow (Y) light and a light-emitting unit that emits blue (B) light; an R·G\B or B\R·G two-unit tandem structure including a light-emitting unit that emits red (R) light and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellow green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order, for example. Note that “a\b” means that one light-emitting unit contains a light-emitting substance that emits light of a and a light-emitting substance that emits light of b.

As illustrated in FIG. 20C, a light-emitting unit including one light-emitting layer and a light-emitting unit including a plurality of light-emitting layers may be used in combination.

Specifically, in the structure illustrated in FIG. 20C, a plurality of light-emitting units (the light-emitting unit 763a, the light-emitting unit 763b, and the light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 20C, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where a display device includes a light-emitting device emitting infrared light, it is preferable that a conductive film transmitting visible light and infrared light be used for the electrode through which light is extracted, and a conductive film reflecting visible light and infrared light be used for the electrode through which light is not extracted.

A conductive film transmitting visible light may be used also for an electrode through which no light is extracted. In this case, this electrode is preferably provided between the reflective layer and the EL layer 763. In other words, light emitted from the EL layer 763 may be reflected by the reflective layer to be extracted from the display device.

As a material that forms the pair of electrodes of the light-emitting device, a metal, an alloy, an electrically conductive compound, a mixture thereof, and the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy) such as an alloy of aluminum, nickel, and lanthanum (Al—Ni—La) and an alloy of silver, palladium, and copper (also referred to as Ag—Pd—Cu or APC). Other example of the material include elements belonging to Group 1 or Group 2 of the periodic table, which are not exemplified above (e.g., lithium, cesium, calcium, and strontium), rare earth metals such as europium and ytterbium, an alloy containing any of these metals in appropriate combination, and graphene.

The light-emitting device preferably employs a microcavity structure. Therefore, one of the pair of electrodes included in the light-emitting device preferably includes an electrode having properties of transmitting and reflecting visible light (a transflective electrode), and the other preferably includes an electrode having a property of reflecting visible light (a reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with a wavelength longer than or equal to 400 nm and shorter than 750 nm) transmittance higher than or equal to 40% is preferably used as the transparent electrode of the light-emitting device. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² Ωcm or lower.

The light-emitting device includes at least the light-emitting layer. In addition, the light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting device, and an inorganic compound may also be included. Each layer included in the light-emitting device can be formed by a method such as an evaporation method (including a vacuum evaporation method), a transfer method, a printing method, an inkjet method, or a coating method.

The light-emitting layer contains one or more kinds of light-emitting substances. As the light-emitting substance, a substance whose emission color is blue, violet, bluish violet, green, yellowish green, yellow, orange, red, or the like is appropriately used. Alternatively, a substance that emits near-infrared light can be used as the light-emitting substance.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property which can be used for the hole-transport layer and will be described later. As the electron-transport material, it is possible to use a material with a high electron-transport property which can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer is a layer injecting holes from an anode to a hole-transport layer and containing a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, an oxide of a metal belonging to any of Group 4 to Group 8 of the periodic table can be used, for example. Specifically, molybdenum oxide, vanadium oxide, niobium oxide, tantalum oxide, chromium oxide, tungsten oxide, manganese oxide, and rhenium oxide are given. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material having a high hole-injection property, a material that contains a hole-transport material and the above-described oxide of a metal belonging to any of Group 4 to Group 8 of the periodic table (typically, molybdenum oxide) may be used, for example.

The hole-transport layer is a layer transporting holes, which are injected from the anode by the hole-injection layer, to the light-emitting layer. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a material with a high hole-transport property such as a π-electron rich heteroaromatic compound (e.g., a carbazole derivative, a thiophene derivative, or a furan derivative) or an aromatic amine (a compound having an aromatic amine skeleton) is preferable.

The electron-blocking layer is provided in contact with the light-emitting layer. The electron-blocking layer is a layer having a hole-transport property and containing a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound including a nitrogen-containing heteroaromatic compound.

The hole-blocking layer is provided in contact with the light-emitting layer. The hole-blocking layer is a layer having an electron-transport property and containing a material that can block holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the LUMO level of the material with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the above-described hole-injection layer.

The charge-generation layer preferably includes a layer containing a material with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can be configured to contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer containing a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, properties, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can suppress an increase in driving voltage.

At least part of this embodiment can be implemented in appropriate combination with the other embodiments described in this specification.

### Embodiment 5

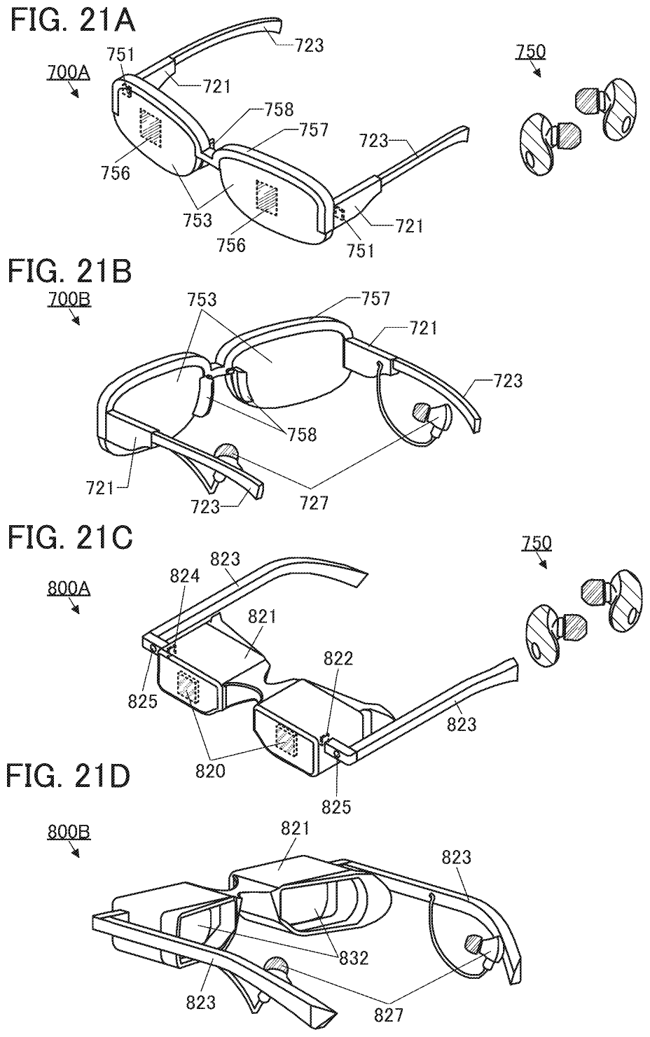

In this embodiment, electronic devices of one embodiment of the present invention will be described using FIG. 21 to FIG. 23.

Electronic devices in this embodiment each include the display panel (display device) of one embodiment of the present invention in a display portion. The display panel of one embodiment of the present invention can easily achieve higher resolution and higher definition and can achieve high display quality. Thus, the display device of one embodiment of the present invention can be used for display portions of a variety of electronic devices.

Examples of the electronic devices include a digital camera, a digital video camera, a digital photo frame, a cellular phone, a portable game machine, a portable information terminal, and an audio reproducing device, in addition to electronic devices with comparatively large screens, such as a television device, a desktop or laptop personal computer, a monitor for a computer or the like, digital signage, and a large game machine such as a pachinko machine.

In particular, the display panel of one embodiment of the present invention can have higher resolution, and thus can be suitably used for an electronic device having a comparatively small display portion. Examples of such an electronic device include wristwatch-type and bracelet-type information terminal devices (wearable devices) and a wearable device that can be worn on a head, such as a device for VR such as a head-mounted display, a glasses-type device for AR, or a device for MR.

The definition of the display panel of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, the definition of 4K, 8K, or higher is preferable. In addition, the pixel density (resolution) of the display panel of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display panel with one or both of high definition and high resolution, realistic sensation, sense of depth, and the like can be further increased. Furthermore, there is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a storage medium.

Examples of wearable devices that can be worn on a head are described using FIG. 21A to FIG. 21D. These wearable devices have one or both of a function of displaying AR contents and a function of displaying VR contents. Note that the wearable devices may have a function of displaying SR or MR contents, in addition to AR and VR contents. The electronic device having a function of displaying contents of at least one of AR, VR, SR, MR, and the like enables the user to reach a higher level of immersion.

An electronic device 700A illustrated in FIG. 21A an electronic device 700B illustrated in FIG. 21B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be employed as the display panel 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, the user can see images displayed on the display regions that are superimposed on transmission images seen through the optical members 753. Thus, the electronic device 700A and the electronic device 700B are electronic devices capable of AR display.

In each of the electronic device 700A and the electronic device 700B, a camera capable of capturing images of the front side may be provided as the image capturing portion. Furthermore, when each of the electronic device 700A and the electronic device 700B is provided with an acceleration sensor such as a gyroscope sensor, the orientation of a user's head can be sensed and an image corresponding to the orientation can be displayed on the display region 756.

The communication portion includes a wireless communication device, and a video signal and the like can be supplied by the wireless communication device. Note that instead of the wireless communication device or in addition to the wireless communication device, a connector to which a cable supplied with a video signal and a power potential can be connected may be provided.

In addition, each of the electronic device 700A and the electronic device 700B is provided with a battery so that charging can be performed wirelessly and/or by wire.

A touch sensor module may be provided in the housing 721. The touch sensor module has a function of detecting a touch on an outer surface of the housing 721. A tap operation, a slide operation, or the like by the user can be detected with the touch sensor module, so that a variety of processings can be executed. For example, processing such as a pause or a restart of a moving image can be executed by a tap operation, and processing such as fast forward or fast rewind can be executed by a slide operation. In addition, the touch sensor module is provided in each of the two housings 721, so that the range of the operation can be increased.

A variety of touch sensors can be employed for the touch sensor module. For example, touch sensors of a variety of types such as a capacitive type, a resistive film type, an infrared type, an electromagnetic induction type, a surface acoustic wave type, and an optical type can be employed. In particular, a capacitive sensor or an optical sensor is preferably employed for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 21C and an electronic device 800B illustrated in FIG. 21D each include a pair of display portions 820, a housing 821, a communication portion 822, a pair of wearing portions 823, a control portion 824, a pair of image capturing portions 825, and a pair of lenses 832.

The display panel of one embodiment of the present invention can be employed in the display portion 820. Thus, the electronic device can perform display with extremely high resolution. This enables the user to feel a high sense of immersion.

The display portions 820 are positioned inside the housing 821 so as to be seen through the lenses 832. Furthermore, when the pair of display portions 820 display different images, three-dimensional display using parallax can be also performed.

Each of the electronic device 800A and the electronic device 800B can be regarded as an electronic device for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lens 832 and the display portion 820 is preferably included.

The electronic device 800A or the electronic device 800B can be worn on the user's head with the wearing portions 823. Note that FIG. 21C and the like illustrate examples where the wearing portion 823 has a shape like a temple of glasses (also referred to as a joint or the like); however, one embodiment of the present invention is not limited thereto. The wearing portion 823 can have any shape with which the user can wear and can have a shape of a helmet or a band, for example.

The image capturing portion 825 has a function of obtaining external information. Data obtained by the image capturing portion 825 can be output to the display portion 820. An image sensor can be used for the image capturing portion 825. Moreover, a plurality of cameras may be provided to support a plurality of fields of view, such as a telescope field of view and a wide field of view.

Note that although an example where the image capturing portion 825 is included is shown here, a range sensor that is capable of measuring the distance between the user and an object (hereinafter such a sensor is also referred to as a sensing portion) is provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more information can be obtained and a gesture operation with higher accuracy is possible.

The electronic device 800A may include a vibration mechanism that functions as bone-conduction earphones. For example, any one or more of the display portion 820, the housing 821, and the wearing portion 823 can include the vibration mechanism. Thus, without additionally requiring an audio device such as headphones, earphones, or a speaker, the user can enjoy a video and sound only by wearing the electronic device 800A.

The electronic device 800A and the electronic device 800B may each include an input terminal. To the input terminal, a cable for supplying a video signal from a video output device or the like, power for charging a battery provided in the electronic device, and the like can be connected.

An electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 21A has a function of transmitting information to the earphones 750 with the wireless communication function. As another example, the electronic device 800A illustrated in FIG. 21C has a function of transmitting information to the earphones 750 with the wireless communication function.

Alternatively, the electronic device may include an earphone portion. The electronic device 700B illustrated in FIG. 21B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic device 800B illustrated in FIG. 21D includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. Alternatively, the electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (the electronic device 700A, the electronic device 700B, or the like) and the goggles-type device (the electronic device 800A, the electronic device 800B, or the like) are suitable as the electronic device of one embodiment of the present invention.

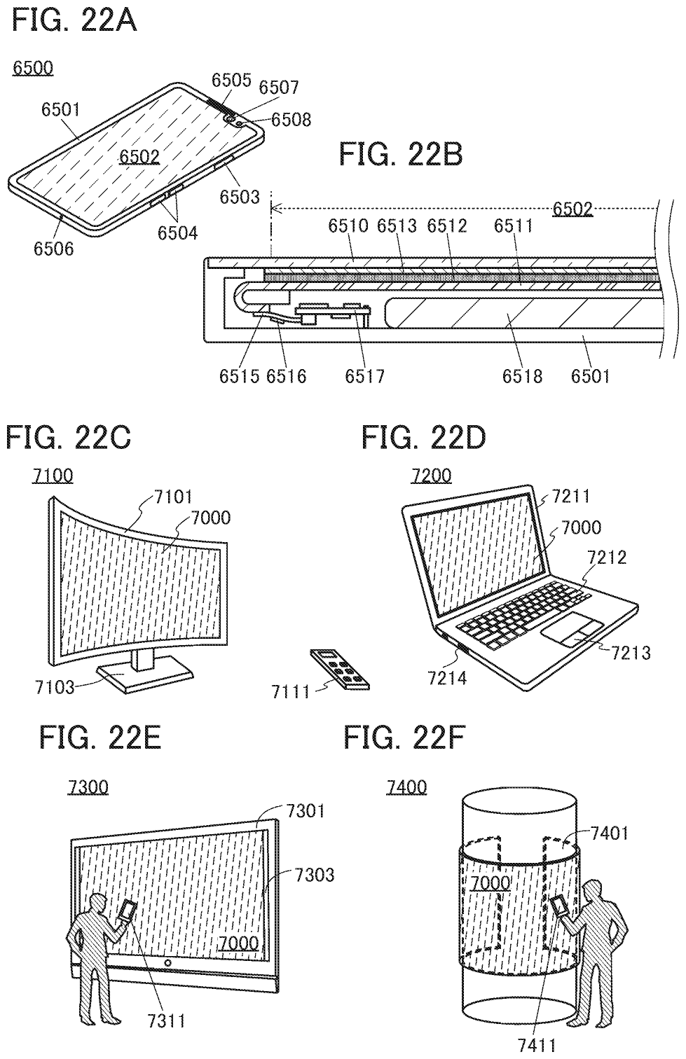

An electronic device 6500 illustrated in FIG. 22A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display panel of one embodiment of the present invention can be employed for the display portion 6502.

FIG. 22B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be employed for the display panel 6511. Thus, an extremely lightweight electronic device can be achieved. In addition, since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of a pixel portion, so that an electronic device with a narrow bezel can be achieved.

FIG. 22C illustrates an example of a television device. In a television device 7100, a display portion 7000 is incorporated in a housing 7101. Here, a structure in which the housing 7101 is supported by a stand 7103 is illustrated.

Operations of the television device 7100 illustrated in FIG. 22C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and sound volume can be operated and a video displayed on the display portion 7000 can be operated.

Note that the television device 7100 includes a receiver, a modem, and the like. A general television broadcast can be received with the receiver. In addition, when the television device is connected to a communication network with or without wires via the modem, one-way (from a transmitter to a receiver) or two-way (between a transmitter and a receiver or between receivers, for example) data communication can be performed.

FIG. 22D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

FIG. 22E and FIG. 22F illustrate examples of digital signage. Digital signage 7300 illustrated in FIG. 22E includes a housing 7301, the display portion 7000, a speaker 7303, and the like. Furthermore, the digital signage 7300 can include an LED lamp, an operation key (including a power switch or an operation switch), a connection terminal, a variety of sensors, a microphone, and the like.

FIG. 22F is digital signage 7400 attached to a cylindrical pillar 7401. The digital signage 7400 includes the display portion 7000 provided along a curved surface of the pillar 7401.

The larger display portion 7000 can increase the amount of information that can be provided at a time. In addition, the larger display portion 7000 attracts more attention, so that advertising effects can be increased, for example.

The use of a touch panel in the display portion 7000 is preferable because in addition to display of an image or a moving image on the display portion 7000, an intuitive operation by the user is possible. Moreover, in the case where the display panel of one embodiment of the present invention is used for providing information such as route information or traffic information, usability can be increased by an intuitive operation.

In addition, as illustrated in FIG. 22E and FIG. 22F, it is preferable that the digital signage 7300 or the digital signage 7400 can work with an information terminal device 7311 or an information terminal device 7411 such as a user's smartphone through wireless communication. For example, information of an advertisement displayed on the display portion 7000 can be displayed on a screen of the information terminal device 7311 or the information terminal device 7411. Furthermore, by the operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (a controller). Thus, an unspecified number of users can join in and enjoy the game concurrently.

The display panel of one embodiment of the present invention can be employed for the display portion 7000 illustrated in each of FIG. 22C to FIG. 22F.

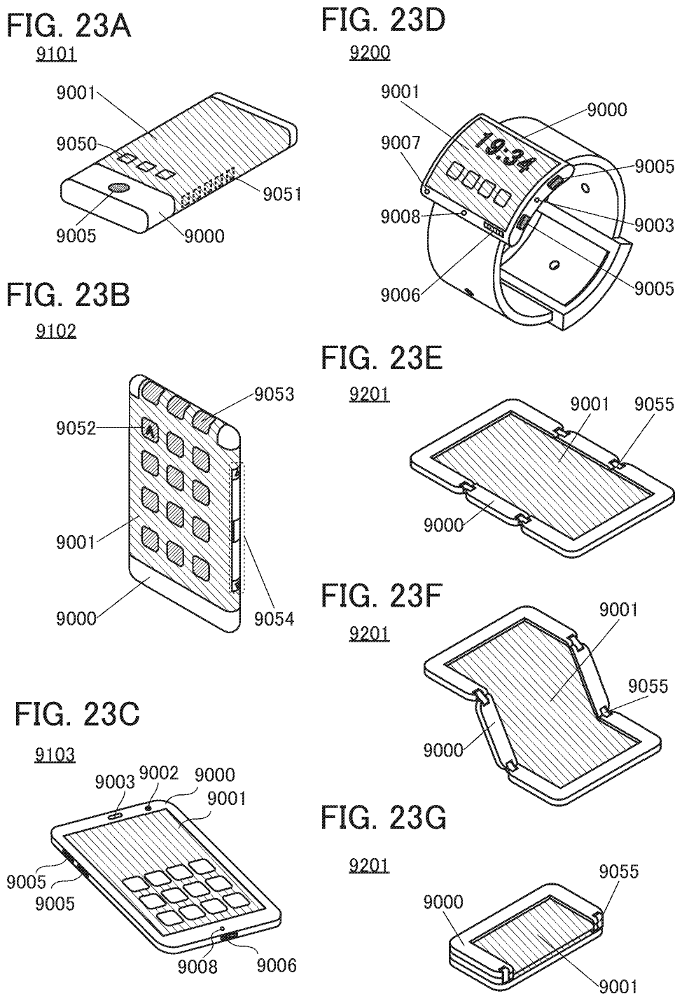

Electronic devices illustrated in FIG. 23A to FIG. 23G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, a distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic devices illustrated in FIG. 23A to FIG. 23G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a storage medium. Note that the functions of the electronic devices are not limited thereto, and the electronic devices can have a variety of functions. The electronic devices may include a plurality of display portions. In addition, the electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices illustrated in FIG. 23A to FIG. 23G are described in detail below.

FIG. 23A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. In addition, the portable information terminal 9101 can display characters and image information on its plurality of surfaces. FIG. 23A illustrates an example in which three icons 9050 are displayed. Furthermore, information 9051 indicated by dashed rectangles can be displayed on another surface of the display portion 9001. Examples of the information 9051 include notification of incoming e-mails, SNS, calls, and the like; the titles and senders of e-mails, SNS, and the like; dates; time; remaining battery; and radio field intensity. Alternatively, the icon 9050 or the like may be displayed at the position where the information 9051 is displayed.

FIG. 23B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 displayed such that it can be seen from above the portable information terminal 9102, with the portable information terminal 9102 put in a breast pocket of his/her clothes. The user can see display without taking out the portable information terminal 9102 from the pocket and determine whether to answer a call, for example.

FIG. 23C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on a front surface of the housing 9000; the operation keys 9005 as buttons for operations on a left side surface of the housing 9000; and the connection terminal 9006 on a bottom surface.

FIG. 23D is a perspective view illustrating a wristwatch-type portable information terminal 9200. For example, the portable information terminal 9200 can be used as a Smartwatch (registered trademark). In addition, a display surface of the display portion 9001 is provided and curved, and display can be performed along the curved display surface. Furthermore, mutual communication between the portable information terminal 9200 and, for example, a headset capable of wireless communication enables hands-free calling. Moreover, with the connection terminal 9006, the portable information terminal 9200 can perform mutual data transmission with another information terminal and charging. Note that a charging operation may be performed by wireless power feeding.

FIG. 23E to FIG. 23G are perspective views illustrating a foldable portable information terminal 9201. In addition, FIG. 23E is a perspective view of an opened state of the portable information terminal 9201, FIG. 23G is a perspective view of a folded state thereof, and FIG. 23F is a perspective view of a state in the middle of change from one of FIG. 23E and FIG. 23G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be bent with a radius of curvature greater than or equal to 0.1 mm and less than or equal to 150 mm.

At least part of this embodiment can be implemented in appropriate combination with the other embodiments described in this specification.

### REFERENCE NUMERALS

100: display device, 101: substrate, 103: insulating layer, 110B: light-emitting element, 110W: light-emitting element, 111C: connection electrode, 111f: conductive film, 111: pixel electrode, 112B: organic layer, 112p: organic layer, 112: organic layer, 113: common electrode, 114: common layer, 115a: conductive layer, 115b: conductive layer, 121: protective layer, 122: insulating layer, 124a: pixel, 124b: pixel, 125f: insulating film, 125: insulating layer, 126f: resin film, 126p: resin layer, 126: resin layer, 135: insulating layer, 140: connection portion, 150a: subpixel, 150B: subpixel, 150b: subpixel, 150c: subpixel, 150G: subpixel, 150R: subpixel, 150: pixel, 151B: subpixel, 151G: subpixel, 151R: subpixel, 152B: subpixel, 152G: subpixel, 152R: subpixel, 152W: subpixel, 170: substrate, 172: light-blocking layer, 174B: coloring layer, 174G: coloring layer, 174R: coloring layer, 174: coloring layer, 175G: color conversion layer, 175R: color conversion layer, 181: insulating layer, 182: adhesive layer

1. A display device comprising a pixel electrode, a first organic layer, a second organic layer, a first insulating layer, a second insulating layer, and a common electrode,
wherein the first insulating layer comprises a first portion in contact with a part of a top surface of the pixel electrode, a second portion in contact with a side surface of the pixel electrode, and a third portion not in contact with the pixel electrode,
wherein the first organic layer comprises a fourth portion in contact with another part of the top surface of the pixel electrode and a fifth portion in contact with the first portion of the first insulating layer,
wherein the second organic layer is in contact with the third portion of the first insulating layer and isolated from the first organic layer,
wherein the second insulating layer covers the fifth portion of the first organic layer and the second organic layer and is in contact with the first insulating layer between the first organic layer and the second organic layer,
wherein the common electrode comprises a portion overlapping with the fourth portion of the first organic layer and a portion overlapping with the second organic layer with the second insulating layer therebetween, and
wherein the first organic layer and the second organic layer comprise the same material.

2. A display device comprising a pixel electrode, an organic layer, a first insulating layer, a second insulating layer, and a common electrode,
wherein the first insulating layer comprises a first portion in contact with a part of a top surface of the pixel electrode, a second portion in contact with a side surface of the pixel electrode, and a third portion not in contact with the pixel electrode,
wherein the organic layer comprises a fourth portion in contact with another part of the top surface of the pixel electrode, a fifth portion in contact with the first portion of the first insulating layer, a sixth portion in contact with the second portion of the first insulating layer, and a seventh portion in contact with the third portion of the first insulating layer,
wherein the second insulating layer covers the fifth portion, the sixth portion, and the seventh portion of the organic layer,
wherein the common electrode comprises a portion overlapping with the fourth portion of the organic layer and a portion overlapping with the seventh portion with the second insulating layer therebetween, and
wherein the sixth portion of the organic layer comprises a region where a thickness is smaller than or equal to half of the fourth portion.

3. The display device according to claim 1, further comprising a resin layer,
wherein the resin layer overlaps with the first insulating layer with the second insulating layer therebetween, and
wherein the common electrode comprises a portion positioned over the resin layer.

4. The display device according to claim 3,
wherein the resin layer has a top surface with a convex shape or a concave shape.

5. The display device according to claim 1, further comprising a first coloring layer and a second coloring layer,
wherein a plurality of the pixel electrodes are included,
wherein one of the pixel electrodes overlaps with the first coloring layer, and
wherein another one of the pixel electrodes overlaps with the second coloring

6. The display device according to claim 1, further comprising a color conversion layer,
wherein a plurality of the pixel electrodes are included,
wherein one of the pixel electrodes overlaps with the color conversion layer, and
wherein another one of the pixel electrodes does not overlap with the color conversion layer.

7. The display device according to claim 6, further comprising a first coloring layer and a second coloring layer,
wherein the first coloring layer overlaps with the one of the pixel electrodes with the color conversion layer therebetween, and
wherein the second coloring layer overlaps with another one of the pixel electrodes.

8. The display device according to claim 6,
wherein the color conversion layer comprises a quantum dot.

9. The display device according to claim 1, further comprising a first color conversion layer and a second color conversion layer,
wherein a plurality of the pixel electrodes are included,
wherein one of the pixel electrodes overlaps with the first color conversion layer, and
wherein another one of the pixel electrodes overlaps with the second color conversion layer.

10. The display device according to claim 9, further comprising a first coloring layer and a second coloring layer,
wherein the first coloring layer overlaps with the one of the pixel electrodes with the first color conversion layer therebetween, and
wherein the second coloring layer overlaps with another one of the pixel electrodes with the second color conversion layer therebetween.

11. The display device according to claim 1, further comprising a transistor in which a channel is formed in silicon,
wherein the pixel electrode is positioned above the transistor.

12. The display device according to claim 1, further comprising a transistor in which a channel is formed in a layer comprising one or both of indium and zinc,
wherein the pixel electrode is positioned above the transistor.

13. The display device according to claim 1, further comprising a first transistor in which a channel is formed in silicon and a second transistor in which a channel is formed in a layer comprising one or both of indium and zinc,
wherein the second transistor is positioned above the first transistor, and
wherein the pixel electrode is positioned above the second transistor.

14. The display device according to claim 2, further comprising a resin layer,
wherein the resin layer overlaps with the first insulating layer with the second insulating layer therebetween, and
wherein the common electrode comprises a portion positioned over the resin layer.

15. The display device according to claim 2, further comprising a first coloring layer and a second coloring layer,
wherein a plurality of the pixel electrodes are included,
wherein one of the pixel electrodes overlaps with the first coloring layer, and
wherein another one of the pixel electrodes overlaps with the second coloring

16. The display device according to claim 2, further comprising a color conversion layer,
wherein a plurality of the pixel electrodes are included,
wherein one of the pixel electrodes overlaps with the color conversion layer, and
wherein another one of the pixel electrodes does not overlap with the color conversion layer.

17. The display device according to claim 2, further comprising a first color conversion layer and a second color conversion layer,
wherein a plurality of the pixel electrodes are included,
wherein one of the pixel electrodes overlaps with the first color conversion layer, and
wherein another one of the pixel electrodes overlaps with the second color conversion layer.

18. The display device according to claim 2, further comprising a transistor in which a channel is formed in silicon,
wherein the pixel electrode is positioned above the transistor.

19. The display device according to claim 2, further comprising a transistor in which a channel is formed in a layer comprising one or both of indium and zinc,
wherein the pixel electrode is positioned above the transistor.

20. The display device according to claim 2, further comprising a first transistor in which a channel is formed in silicon and a second transistor in which a channel is formed in a layer comprising one or both of indium and zinc,
wherein the second transistor is positioned above the first transistor, and
wherein the pixel electrode is positioned above the second transistor.
